(19) United States
(12) Patent Application Publication
(10) Pub. No.: US 2026/0088911 A1
(43) Pub. Date: Mar. 26, 2026

(54) OPTICAL QUANTUM NETWORKS WITH CONNECTIVITY BASED ON REGULAR GRAPHS

(71) Applicant: PHOTONIC INC., Coquitlam (CA)

(72) Inventors: Stephanie SIMMONS, Burnaby (CA); Camille CHARTRAND, Burnaby (CA); Evan MACQUARRIE, Burnaby (CA)

(21) Appl. No.: 19/112,761

(22) PCT Filed: Sep. 19, 2023
(86) PCT No.: PCT/CA2023/051240

§ 371 Date: Mar. 18, 2025

Related U.S. Application Data
(60) Provisional application No. 63/377,341, filed on Sep. 27, 2022.
(60) Provisional application No. 63/501,587, filed on May 11, 2023.

(51) Int. Cl. H04B 10/70; G06N 10/20; G06N 10/40; H04B 10/272; H10N 60/12

(52) U.S. Cl. CPC H04B 10/70; G06N 10/20; G06N 10/40; H04B 10/272; H10N 60/12

(57) ABSTRACT

Quantum networks having topologies defined by connected entanglement graphs which comprise plural vertices connected by plural edges are disclosed. The entanglement graphs are not all-to-all connected. The entanglement graphs may be non-planar graphs. At least some of the vertices are connected to three or more of the edges. Nodes of the quantum network correspond to vertices of the entanglement graph. Entanglement means are operable to directly entangle quantum systems in those pairs of the nodes which respectively correspond to vertices of the entanglement graph that are connected by an edge of the entanglement graph. Optical paths used by the entanglement means may include optical paths provided by braids or knots that are configured to interface to one or more units which include the nodes.

### CROSS-REFERENCE TO RELATED APPLICATIONS

This application claims priority from U.S. application No. 63/377,341 filed 27 Sep. 2022 and entitled OPTICAL QUANTUM NETWORKS WITH CONNECTIVITY BASED ON REGULAR GRAPHS and U.S. application No. 63/501,587 filed 11 May 2023 and entitled OPTICAL QUANTUM NETWORKS WITH CONNECTIVITY BASED ON REGULAR GRAPHS which are hereby incorporated herein by reference for all purposes. For purposes of the United States of America, this application claims the benefit under 35 U.S.C. § 119 of U.S. application No. 63/377,341 filed 27 Sep. 2022 and entitled OPTICAL QUANTUM NETWORKS WITH CONNECTIVITY BASED ON REGULAR GRAPHS and U.S. application No. 63/501,587 filed 11 May 2023 and entitled OPTICAL QUANTUM NETWORKS WITH CONNECTIVITY BASED ON REGULAR GRAPHS which are hereby incorporated herein by reference for all purposes.

### FIELD

This technology relates to methods and systems for quantum information management. Aspects of the technology relate to quantum networks that have geometries defined by graphs that have certain advantageous properties. Aspects of the technology also relate to apparatus and methods for constructing quantum networks that have defined topologies. The technology has example application in creating and exploiting entanglement of quantum states of quantum systems.

### BACKGROUND

Quantum informatics involves storing and/or manipulating information represented by the state of a quantum system or a set of quantum systems. Quantum information may, for example, be represented by the states of quantum systems as diverse as photons, Josephson junctions (superconducting qubits), electron spins and nuclear spins in solid state defects, trapped ions and others.

Quantum informatics is a rapidly developing field. There is a strong demand for quantum networks capable of managing and manipulating large amounts of quantum information. While one can readily scale up the number of quantum systems (e.g. qubits) in a quantum information processing network it is a significant technical problem to provide interconnectivity that will provide desired interactions between the quantum systems, for example to transfer quantum information within the network, perform quantum gates on pairs or groups of quantum systems within the network, create quantum entanglement of quantum systems etc. A problem recognized by the inventors is that the number of possible interconnections and the distances over which such interconnections operate both increase rapidly as the size of a quantum network increases

Quantum entanglement can be used to facilitate interactions between quantum systems even where the quantum systems are separated by large distances.

One type of quantum network is an optical quantum network which uses photons to carry quantum information among different matter-based quantum systems. Photons may be carried on optical links. Optical switches may be provided to guide photons along selected paths. As the size of an optical quantum network is scaled to include more quantum systems the size and complexity of the system of optical links that provides interconnectivity between the quantum systems also increases. A problem recognized by the inventors is that the likelihood that a photon will be lost is increased when a system of optical links is scaled to provide greater connectivity.

There is a need for optical quantum networks with scalable connectivity.

### SUMMARY

The present technology has a number of aspects that include, without limitation:
systems operative to perform quantum informatics and quantum computation in a scalable quantum network;
systems that include nodes containing quantum systems, optical paths and Bell State analyzers that are configured to conduct scalable concurrent quantum computations;
connectivity schemes for a scalable quantum network; and
methods for performing quantum entanglement in a scalable optical quantum network.

One aspect of the invention provides a quantum network. The quantum network has a topology characterized by a connected entanglement graph which comprises a plurality of vertices and a plurality of edges. Each of the edges joins a pair of the vertices. The entanglement graph is not all-to-all connected and at least some of the vertices are connected to three or more of the edges. The quantum network comprises a plurality of nodes. Each of the nodes corresponds to a vertex of the entanglement graph. Each of the nodes comprises at least one quantum system that has a quantum state configurable to store quantum information for a quantum informatics process. The plurality of nodes includes

$$\frac{N ( N - 1 )}{2}$$

distinct pairs of nodes where N is the number of the nodes. The network includes entanglement means exclusively operable on those of the pairs of the nodes which respectively correspond to vertices of the entanglement graph that are connected by an edge of the entanglement graph. The entanglement means is operable for pairwise entangling quantum systems that are respectively located at different nodes of any of the pairs of the nodes which correspond to vertices of the entanglement graph that are connected by an edge of the entanglement graph. A non-limiting example of entanglement means is one or more Bell state analyzers that has first and second inputs and an optical network configurable to respectively optically couple each node of one or more pairs of the nodes to the first and second inputs of the Bell state analyzer.

In some embodiments the entanglement means comprises one or more Bell state analyzer (BSA) having first and second input ports and for each of the pairs of the nodes which respectively correspond to vertices of the entanglement graph that are connected by an edge of the entanglement graph, a corresponding pair of first and second optical paths respectively providing optical coupling of first and second nodes of the pair of nodes to the first and second input ports of the BSA.

In some embodiments at least some of the optical paths include a free space optical path. In some embodiments at least some of the optical paths include an optical fiber.

In some embodiments the quantum systems comprise electron spins.

In some embodiments the entanglement means comprises, for each of the pairs of the nodes which respectively correspond to vertices of the entanglement graph that are connected by an edge of the entanglement graph, one or more shuttle paths. The one or more shuttle paths are operable to bring the quantum systems that are to be pairwise entangled to a common location; and
a control system operable to entangle the quantum systems that are to be pairwise entangled at the common location by applying one or more quantum gates to the quantum systems that are to be pairwise entangled at the common location. In some embodiments the quantum systems comprise trapped ions or quantum dots.

In some embodiments the entanglement means comprises, for each of the pairs of the nodes which respectively correspond to vertices of the entanglement graph that are connected by an edge of the entanglement graph, an electronic circuit operable to couple the quantum systems that are to be pairwise entangled; and a control system (e.g. a quantum gate controller) operable to entangle the quantum systems that are to be pairwise entangled by applying one or more quantum gates to the quantum systems that are to be pairwise entangled. In some embodiments the quantum systems comprise superconducting Josephson junctions.

In some embodiments the entanglement graph is a regular graph. In some embodiments the entanglement graph is a strongly regular graph. In some embodiments the entanglement graph is a distance regular graph. In some embodiments the entanglement graph is non-planar.

In some embodiments the entanglement graph consists of a regular graph and one or more dangling vertices, each dangling vertex connected to a single vertex of the regular graph by an edge.

In some embodiments the entanglement graph comprises a plurality of distinct subsets of the vertices that are all-to-all connected, each of the subsets being made up of M vertices, and for each of the subsets of the vertices none of the vertices of the entanglement graph that does not belong to the subset of the vertices is connected by respective edges to every one of the vertices of the subset of the vertices.

In some embodiments the quantum network comprises a control system that is configured to create entanglement between first and second ones of the quantum systems that are respectively associated with first and second ones of the nodes that are associated with vertices of the entanglement graph that are not connected by an edge by: controlling the entanglement means to create a plurality of entangled pairs of the quantum systems, one of the plurality of entangled pairs of the quantum systems including the first one of the quantum systems and another one of the plurality of entangled pairs of the quantum systems including the second one of the quantum systems; and performing entanglement swapping to cause the first and second ones of the quantum systems to be entangled.

In some embodiments the entanglement means is operable to generate the entanglement of one of the pairs of quantum systems by: routing a travelling qubit associated with a first quantum system of the pair of quantum systems to the node associated with a second quantum system of the pair of quantum systems, and executing an entanglement protocol on the travelling qubit associated with the first quantum system and a travelling qubit associated with the second quantum system. In some embodiments routing the travelling qubit associated with the first quantum system comprises routing the travelling qubit on a path that passes through one or more intermediary nodes. In some embodiments each of the one or more intermediary nodes includes one or more switches that is configurable to allow the travelling qubit to traverse the intermediary node and to block the travelling qubit from interacting with quantum systems of the intermediary node.

In some embodiments the node associated with the second quantum system includes a Bell State Analyzer (BSA) that is operable to perform a Bell State Measurement (BSM) on the travelling qubits associated with the first and second quantum systems to thereby generate entanglement between the pair of quantum systems.

In some embodiments the entanglement means comprises a plurality of Bell state analyzers (“BSAs”) each comprising plural inputs, wherein each of the edges of the entanglement graph connects a pair of the vertices that corresponds to a pair of the nodes made up of a first node and a second node and first and second inputs of at least one of the BSAs are respectively physically or optically linked to the first and second nodes.

In some embodiments the topology of the quantum network is defined at least in part by a knot or a braid.

Another aspect of the invention provides an optical quantum network comprising a plurality of nodes. Each of the nodes comprises at least one quantum system. The at least one quantum system of each of the nodes has an optical transition. Each of the nodes is optically coupled to one or more Bell state analyzers by optical links to provide connectivity that corresponds to a strongly regular connected entanglement graph made up of vertices and edges that each connect two of the vertices. The entanglement graph includes some pairs of vertices that are not connected to one another by any one of the edges and other pairs of vertices that are connected to one another by one of the edges. The vertices of the entanglement graph correspond to the nodes. The edges of the entanglement graph correspond to connectivity of each of the nodes corresponding to the vertices joined by the edge to one of the one or more Bell state analyzers. The optical links are configured so that where an edge of the graph joins vertices that correspond to two of the nodes, the optical links provide connectivity of each of the two of the nodes to a respective input port of the same Bell state analyzer such that the Bell state analyzer can perform a Bell state measurement on photons received from the pair of nodes. Where two vertices are not joined by an edge the optical links do not provide connectivity of the nodes corresponding to the two vertices to the same Bell state analyzer. The plurality of nodes is provided by N of the nodes with N≥4.

In some embodiments the network comprises M detector units. Each detector unit comprises at least one Bell state analyzer and a plurality of P optical ports. Each of the N nodes has a plurality Q of optical ports and at least some of the Q optical ports of each of the nodes are each connected to a respective one of the P optical ports of a respective one of the detector units such that each of the N nodes is connectable with any one of K other ones of the N nodes to a respective one of the Bell state analyzers of the optical network where 2≤K<N−1.

In some embodiments the optical network includes a plurality of light guides with one of the light guides connecting each of the at least some of the Q optical ports of each of the N nodes to a corresponding one of the P optical ports of a respective one of the detector units. In some embodiments the at least one Bell state analyzer comprises a plurality of Bell state analyzers and the optical links are configured to provide concurrent connection of each of the plurality of Bell state analyzers to a pair of the nodes. In some embodiments each of the detector units comprises two or more optical ports and one or more optical switches operative to connect any pair of the optical ports of the detector unit to one of the at least one Bell state analyzer.

In some embodiments the regular entanglement graph is characterized by the parameter set (v, k, λ, μ) where v=N is the number of vertices of the graph, k=K is the number of edges connected to each vertex, λ is the number of common neighbours for each pair of adjacent vertices where the common neighbours are joined to each of the pair of vertices by an edge and μ is the number of common neighbours for pairs of non-adjacent vertices in the entanglement graph. In some embodiments k>2. In some embodiments k>3. In some embodiments The network according to claim 27 where λ≥1 and μ≥1. In some embodiments v=243 and k=22.

In some embodiments at least some of the one or more Bell state analyzers and at least some of the plurality of nodes are on a common substrate. In some embodiments all of the one or more Bell state analyzers of the M detector units and all of the plurality of N nodes are on a common substrate.

Another aspect of the invention provides an optical quantum network comprising: one or more substrates, a plurality of detector units that each comprise at least one Bell state analyzer on the one or more substrates; and a plurality of nodes on the one or more substrates. Each of the nodes comprises at least one quantum system. One or more of the quantum systems of each of the nodes has an optical transition. Each of the plurality of nodes includes an optical structure that includes at least one optical coupler on the one or more substrate. The optical coupler is in optical communication with at least one of the one or more quantum systems of the node that has an optical transition. The detector units each have a plurality of input ports that are respectively optically coupled to a corresponding optical coupler on the one or more substrate. Each of the plurality of nodes is optically coupled to one or more of the Bell state analyzers by optical links provided by a braid or knot that includes light guides that optically couple one of the optical couplers associated with one of the nodes to one of the optical couplers associated with one of the detector units.

In some embodiments the at least one substrate comprises a plurality of the substrates and the nodes and detector units are distributed over the plurality of substrates.

In some embodiments at least one of the substrates comprises a plurality of the detector units and none of the nodes.

In some embodiments at least one of the substrates comprises a plurality of the nodes and none of the detector units.

In some embodiments one or more of the nodes incorporates one of the detector units.

In some embodiments the nodes and the detector units are on different ones of the substrates.

In some embodiments the at least one substrate comprises a common substrate and the nodes and the detector units are on the common substrate.

In some embodiments the at least one optical coupler comprises a plurality of optical couplers each associated with one of the light guides and the optical structure comprises one or more switches configurable to selectively direct photons from the at least one quantum system of the node to one of the plurality of optical couplers.

In some embodiments at least some of the one or more switches are integrated with the respective one or more nodes on the one or more substrates.

In some embodiments the light guides comprise optical fibers.

In some embodiments the optical quantum network comprises a switch that has plural input ports. Each of the plural input ports coupled to a respective coupler associated with a respective one of the nodes by a respective one of the light guides. The switch is configurable to selectively couple one of the input ports to a first input of a BSA (Bell state analyzer).

In some embodiments the light guides comprise optical fibers.

In some embodiments the optical quantum network comprises a lattice structure configured to support the braid or knot, the lattice structure shaped to define a plurality of tunnels within the lattice structure wherein the light guides of the braid or knot extend through the plurality of tunnels.

In some embodiments the lattice structure is shaped to define an array of endpoints on one or more faces of the lattice structure wherein the array of endpoints on each of the one or more faces of the lattice structure corresponds to the optical couplers of the plurality of nodes on a corresponding face of the one or more substrates.

In some embodiments the lattice structure is 3D printed.

In some embodiments the lattice structure is integrated with the light guides of the braid or knot such that the light guides are 3D printed along with the lattice structure.

In some embodiments the lattice structure comprises a mechanism for the light guides to reconfigure their positions in the plurality of tunnels of the lattice structure such that the lattice structure is configurable to support a plurality of different braids or knots.

In some embodiments the braid or knot comprises at least one support structure that supports ends of some or all of the light guides at locations that correspond to each of a plurality of the optical couplers.

Another aspect of the invention provides an optical network that comprises a plurality of photon sources optically coupled to one or more photon detectors by optical links to provide connectivity that corresponds to a connected graph made up of vertices and edges that each connect two of the vertices. The graph includes some pairs of vertices that are not connected to one another by an edge and other pairs of vertices that are connected to one another by an edge. The vertices of the graph correspond to the photon sources. The edges of the graph correspond to connectivity of each of the photon sources corresponding to the vertices joined by the edge to one of the one or more photon detectors. The optical links are configured so that where an edge of the graph joins vertices that correspond to two of the photon sources, the optical links provide connectivity of each of the two of the photon sources to a respective input port of the same photon detector. Where two vertices are not joined by an edge the optical links do not provide connectivity of the photon sources corresponding to the two vertices to the same photon detector.

In some embodiments the connected graph is a non-planar graph.

In some embodiments the connected graph is a regular graph.

In some embodiments the connected graph is a distance-regular graph.

In some embodiments the connected graph is a strongly regular graph.

In some embodiments the connected graph is a strongly regular graph characterized by the parameter set (v, k, λ, μ) where v=N is the number of vertices of the graph, k=K is the number of edges connected to each vertex, λ is the number of common neighbours for each pair of adjacent vertices where the common neighbours are joined to each of the pair of vertices by an edge and μ is the number of common neighbours for pairs of non-adjacent vertices in the graph. In some embodiments λ≥1 and μ≥1. In some embodiments λ=1 and μ=2.

In some embodiments v=243 and k=22.

Another aspect of the invention provides a network of quantum systems operable for performing quantum informatics processing. The network comprises a plurality of nodes. Eof the nodes comprising one or more of the quantum systems. The network includes means for establishing inter-node entanglement between pairs of the quantum systems that are in different ones of the nodes and a topology of the network is characterized by an entanglement graph that is a non-planar graph.

In some embodiments the entanglement graph is regular. In some embodiments the entanglement graph is distance regular. In some embodiments the entanglement graph is strongly regular.

In some embodiments the network comprises at least five of the nodes.

Another aspect of the invention provides a method for performing quantum entanglement in an optical quantum network. The optical quantum network comprises N nodes. Each node comprises at least two quantum systems. Each of the N nodes comprises Q outbound optical ports. Each of the optical ports is optically coupled to at least one of the quantum systems of the node. The optical quantum network also comprises M detector units each of which comprises P inbound ports, and at least one Bell state analyzer connectable to receive and perform a Bell state measurement on photons from any pair of the P inbound ports of the detector unit. At least some of the inbound ports of each detector unit are respectively optically coupled to a respective one of the outbound optical ports of one of the nodes such that for each of the detector units, each of the at least some of the inbound optical ports is optically connectable to one of the Q optical outbound ports of a different one of the nodes and the Q optical outbound ports for each of the N nodes are each optically connected to one of the inbound optical ports of a different respective one of the detector units such that each of the N nodes is connectable concurrently with any one of K other ones of the nodes to one of the Bell state analyzers of the optical network where 2≤K<N−1.

The nodes may be arranged in a topology corresponding to a strongly regular connected graph made up of vertices and edges that each connect two of the vertices. The graph includes some pairs of vertices that are not connected to one another by an edge and other pairs of vertices that are connected to one another by an edge. The vertices of the graph correspond to the nodes. The edges of the graph correspond to connectivity of each of the nodes corresponding to the vertices joined by the edge to one of the one or more Bell state analyzers. The method comprises: receiving a request to entangle quantum states of quantum systems of a first one of the nodes and a second one of the node where the first and second nodes respectively correspond to vertices of the graph that are not connected by an edge; finding a path made up of a set of two or more edges that connect the vertices corresponding to the first and second nodes by way of one or more intermediate vertices of the graph;
entangling a quantum system of the first node with a quantum system of a node corresponding to one of the one or more intermediate vertices and entangling a quantum system of the second node with a quantum system of the node corresponding to the one of the one or more intermediate vertices; and performing one or more entanglement swap operations to extend the entanglement to the first and second nodes.

Another aspect of the invention provides apparatus having any new and inventive feature, combination of features, or sub-combination of features as described herein.

Another aspect of the invention provides methods having any new and inventive steps, acts, combination of steps and/or acts or sub-combination of steps and/or acts as described herein.

Further aspects and example embodiments are illustrated in the accompanying drawings and/or described in the following description.

It is emphasized that the invention relates to all combinations of the above features, even if these are recited in different claims.

### BRIEF DESCRIPTION OF THE DRAWINGS

The accompanying drawings illustrate non-limiting example embodiments of the invention.

FIG. 1A-1 to 1A-3 are schematic illustrations showing a side view of a layered substrate structure in a quantum network according to example embodiments.

FIG. 1B-1 is a top view of an example optical structure according to an embodiment.

FIG. 1B-2 is a top view of another example optical structure according to an embodiment.

FIG. 1D-1 is a top view of an example optical structure that includes a switch according to an embodiment.

FIG. 1D-2 is a top view of an example optical structure that includes an off-chip switch according to an embodiment.

FIG. 1E-1 is a schematic top view of a quantum network system according to an embodiment.

FIG. 1E-2 is a schematic perspective view of a quantum network system according to an embodiment.

FIG. 1F is a schematic top view of another quantum network system according to an embodiment.

FIG. 1G is a schematic view of a photon detector unit according to an embodiment.

FIG. 1H is a schematic view of a control system for a quantum network according to an example embodiment.

FIG. 1J-1 is a schematic top view of an optical quantum network according to another example embodiment.

FIG. 1J-2 is a perspective view of an optical quantum network according to another example embodiment.

FIG. 1K schematically illustrates a node of a quantum network according to an example embodiment.

FIG. 1L schematically illustrates a node of a quantum network according to another example embodiment.

FIG. 1M-1 is a schematic illustration of an example node and associated control inputs.

FIG. 1M-2 is a schematic view of an example optical quantum network according to another embodiment which includes several nodes that are the same or similar to the node illustrated in FIG. 1M-1.

FIG. 1M-3 is a schematic illustration of an example Bell state analyzer.

FIG. 2A is a schematic view of an optical quantum network according to an example embodiment.

FIG. 2B is a schematic view of a detector unit according to an example embodiment.

FIG. 2C is a graph representing the connectivity of the optical quantum network of FIG. 2A.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense.

### Network Topologies

One aspect of the present technology relates to topologies for networks of quantum systems that may be used to process quantum information. The topologies correspond to specified entanglement graphs.

Each quantum system may store information in a quantum state of the quantum system. The quantum system may, for example, comprise two or more basis states. In general, the quantum state of the system may be represented by:

$${\vert ψ 〉 = {\sum }_{i = 1}^{Q} {α}_{i} \vert φ 〉}_{i}$$

where: |ψ [symbol] is the quantum state, Q is the number of basis states, αᵢ are complex coefficients, and |φ [symbol] ᵢ are the basis states. Importantly the quantum state |ψ [symbol] may be a superposition (linear combination) of the basis functions |φ [symbol] ᵢ.

In many applications quantum informatics uses two basis states of a quantum system to store quantum information. In such cases the quantum system may be referred to as a qubit . . . . The quantum state of a qubit may be represented by a point on the Bloch sphere.

A qubit can be provided by a two level quantum system such as an electron spin, a nuclear spin, or a photon (a “physical qubit”). The term qubit can also be used in a more abstract sense as a two level quantum system that does not necessarily correspond to a single physical qubit (a “virtual qubit”). A virtual qubit may be implemented by one, two, or more physical quantum systems. For example, a virtual, qubit may be implemented by a set of quantum systems that includes one or more quantum systems that act as brokers which can be used to transfer quantum information into quantum states of one or more other quantum systems that act as clients to store the quantum information. As another example a virtual qubit can be implemented by a plurality of physical qubits which store quantum information of the virtual qubit in a chosen code (e.g. an error correcting code).

An example of a physical quantum system that may be used as a qubit is a particle that has intrinsic spin of ½ (e.g. an electron, a hole or some nuclear spins). In such particles the basis states can be “spin up”, represented by |↑ [symbol] and “spin down”, represented by |↓ [symbol] . Another example of a quantum system that may be used as a qubit is a photon, in which case the basis states may comprise polarization states, time bin states, or states involving other photon properties. Other examples of quantum systems that may be used as qubits include:
superconducting qubits;
trapped ions;
quantum dots;
etc.

Quantum information may be processed by applying operations to quantum systems. Examples of operations that may be applied in quantum informatics include:
Entanglement operations which cause quantum states of two or more distinct qubits to be coupled such that the combined state of the distinct qubits cannot be described by the state of each of the distinct qubits individually.
Measurement operations which measure the state of a qubit. Depending on the initial state of the qubit, a measurement may cause a change in the state of the qubit.
Measurement operations which measure combined states of two or more qubits. An example of a two qubit measurement operation is a Bell State Measurement (BSM).
Initialization operations which set a qubit to a specific state.
Single qubit gates which change the state of a single qubit.
Two qubit gates which operate on two qubits. Examples of two qubit gates include: controlled gates such as CNOT gates, controlled phase gates, in which a single qubit gate operates on one qubit in a way which depends on the state of a second qubit; SWAP gates in which the states of two qubits are traded so that the final state of the first qubit is the initial state of the second qubit and vice versa.
Multi-qubit gates that operate on two or more qubits. For example: the Toffoli gate which operates on three qubits.

The steps required to apply any of the above single qubit operations to a specific qubit depend on the nature of the qubit. The steps required to apply any of the above operations that involve two or more qubits depends on the nature(s) of the qubits and can also depend on the nature of connectivity among the two or more qubits.

Most quantum informatics requires joint interactions involving two or more qubits (e.g. plural qubit joint measurements, plural qubit gates). If two qubits are sufficiently coupled to one another then, depending on the nature of the qubits, such joint interactions may be invoked by applying appropriate electromagnetic signals (e.g. specially designed sets of electromagnetic pulses, which, depending on the nature of the qubits, may have frequencies in the range of radiofrequency to optical frequencies). For two qubits to be coupled sufficiently to facilitate such joint measurements it is usually necessary for the two qubits to be quite close together. For example, two qubits may be sufficiently coupled when their quantum mechanical wavefunctions have significant overlap. Two qubits which are each provided by an intrinsic spin of a particle, such as an electron, hole or atomic nucleus may, for example, be electromagnetically coupled (e.g. by hyperfine coupling or spin-orbit coupling). Such electromagnetic coupling generally occurs only over relatively short ranges.

As the field of quantum informatics develops it is becoming apparent that there are a wide range of applications which will require processing quantum information across a large number of physical quantum systems. When processing quantum information using quantum states of a given number of physical quantum systems, it may not be possible or practical to arrange the physical quantum systems in a way that joint interactions between any pairs or groups of the quantum systems may be readily invoked.

Nonetheless, it is possible to cause joint interactions of quantum states of physical quantum systems that are separated by arbitrary distances and/or are not coupled using quantum entanglement. For example, quantum entanglement may be applied to teleport two qubit gates and to teleport quantum states over arbitrary distances.

Entanglement of two quantum systems may be created in various ways. These include:
two quantum systems that are sufficiently coupled (as described above) may be placed into a desired two qubit entangled state by applying a selected sequence of electromagnetic pulses;
two quantum systems may be entangled by creating a pair of entangled photons, interacting each photon with a respective quantum system and subsequently performing a BSM on the photons;
two quantum systems may be entangled by causing each of the quantum systems to emit a photon that is entangled with the respective quantum system and performing a BSM on the emitted photons.

Each of these is an example of “direct” entanglement. “Direct” entanglement describes a process for entangling two matter-based quantum systems without the need to consume a pre-existing entanglement between other matter-based quantum systems.

Entanglement swapping is an alternative to direct entanglement. Entanglement swapping is a process according to which entanglement between a first quantum system (“A1”) and a second quantum system (“B1”) is created by entangling first quantum system A1 with another quantum system (“A2”), entangling second quantum system B1 with another quantum system (“B2”) and then swapping the entanglement to be entanglement of quantum systems A1 and B1 by performing a BSM on quantum systems A2 and B2. Entanglement swapping may be used to entangle two quantum systems even in cases where there is no available means for directly entangling the two quantum systems.

One aspect of this invention relates to advantageous topologies for quantum networks. These topologies may be described by entanglement graphs. An entanglement graph includes a plurality of vertices, each of which corresponds to a node.

The vertices of the entanglement graph are connected to one another by edges. The presence of an edge between two vertices indicates that there is a mechanism for directly entangling quantum systems associated with the two vertices. The absence of an edge between two vertices indicates that there is no mechanism for directly entangling quantum systems associated with the two vertices. An entanglement graph is preferably “connected”, where “connected” means that it is possible to travel between any two vertices of the entanglement graph by traversing one or more edges. In a quantum network described by a connected entanglement graph, it is possible to create entanglement between quantum systems associated with any two vertices by direct entanglement if the two vertices are connected by an edge and for any two vertices in the connected entanglement graph by entanglement swapping and/or by using quantum teleportation to transfer one or more of two entangled quantum states such that the two entangled quantum states are respectively stored in first and second quantum systems which are associated with different vertices of the connected entanglement graph.

It is notionally ideal to provide a quantum network that corresponds to an entanglement graph that has “all-to-all connectivity” (i.e. every vertex is connected by edges to every other vertex). This would provide complete flexibility by permitting quantum systems associated with any two vertices of the graph to be directly entangled. Yet, for an entanglement graph that has N vertices, all-to-all connectivity requires N×(N−1)/2 edges. Consequently, a quantum network derived from such an entanglement graph needs to include mechanisms operable to achieve direct entanglement on N×(N−1)/2 distinct pairs of nodes. As will be appreciated, this may become impractical as the number of nodes becomes large. For example, an all-to-all connected entanglement graph with only 500 vertices has 124,750 edges (or distinct pairs of nodes). An all-to-all connected entanglement graph with 2000 vertices has nearly 2 million edges (or distinct pairs of nodes).

In some embodiments an optical network includes at least 50 nodes or at least 100 nodes or at least 250 nodes or at least 500 nodes.

### Example Optical Network

Consider the example case of a network of quantum systems provided by N spaced-apart quantum systems that can interact optically (e.g. N electron spins which each have a spin selective optical transition). Pairs of the electron spins may be entangled, for example by performing a photon mediated entanglement protocol directly between two of the electron spins. An example of such an entanglement protocol is a Barrett-Kok entangling scheme, for example as described in Sean D. Barrett, Pieter Kok Efficient high-fidelity quantum computation using matter qubits and linear optics, Phys. Rev. A 71, 060310(R) (2005) which is hereby incorporated herein by reference for all purposes. The Barrett-Kok entanglement scheme uses a Bell state analyzer (“BSA”) for entanglement generation. Assuming the network is based on an all-to-all connected entanglement graph such that each electron spin in the network corresponds to a node on the entanglement graph, it follows that for each pair of nodes connected by an edge, the quantum network must include means to direct photons from electron spin associated with each node in the pair of nodes to corresponding inputs of the same BSA. There are various ways that this can be achieved. However, providing all-to-all connectivity generally requires hardware that becomes significantly more complicated (e.g. requiring more BSAs and/or a more complicated arrangement of optical switches) as N increases.

One way to provide for direct entanglement between quantum systems of any two nodes in a quantum network is to provide a separate dedicated BSA together with light guides or other means for directing photons to the inputs of the BSA. With this construction, each edge of an entanglement graph corresponds to one BSA of the quantum network, the associated optical connections, and associated control circuits.

One can provide for direct entanglement between quantum systems of any two nodes in a quantum network that includes fewer BSAs than the number of edges in an entanglement graph by including an optical switching network that can be selectively configured to direct photons that are entangled with electron spins corresponding to any of two or more pairs of nodes to the same BSA. A single BSA together with a suitably configured optical switching network may further be used to provide direct entanglement between any two nodes of a quantum network of any size. Issues to overcome with this approach include: the cost of an optical switch increases significantly with the number of inputs and outputs of the switch, switches with a plurality of inputs and outputs are generally lossy, and where the same BSA is used to provide for direct entanglement of quantum systems at two or more pairs of nodes the BSA can only be used to attempt entanglement on one pair of qubits at any time.

Another approach to providing a quantum network with N nodes and an all-to-all connected entanglement graph is to scale the number of BSAs in proportion to the number of nodes. For example, a network may include an N×N optical switch which may be operated to pairwise couple any two of the N nodes to the input ports of one of N/2 BSAs. The same switch may simultaneously couple other pairs of qubits to the input ports of other BSAs. This configuration allows multiple entanglement attempts to be performed simultaneously. However, an N×N switch scales poorly with N. Furthermore, such switches are very expensive for large N and photon losses typically increase as N increases.

### Example Topologies for Quantum Networks

Some aspects of the present technology provide quantum networks that have topologies that correspond to entanglement graphs that are not all-to-all connected. This can significantly reduce complexity of the corresponding network.

Entanglement of quantum systems at pairs of nodes corresponding to vertices that are not connected by edges may be achieved by performing entanglement swapping. Entanglement swapping is a technique that uses one or more qubits as a mediator to form entanglement between two qubits. The two qubits that become entangled do not need to share a direct entanglement path (i.e. the two qubits are not required to be located at nodes that correspond to vertices that are joined by an edge in the entanglement graph).

Another option for working with a quantum network corresponding to an entanglement graph that is not all-to-all connected is to avoid the need to create entanglement between nodes that correspond to vertices that are not connected by edges of the entanglement graph. This may be done by using quantum teleportation to move one or more quantum states to quantum systems located at nodes that correspond to vertices that are connected by edges of the entanglement graph. Quantum teleportation consumes entanglement.

As the number of nodes in a quantum network is increased, the reduction in physical complexity that can be achieved by arranging the quantum network to correspond to an entanglement graph that is not all-to-all connected outweighs the increase in control complexity introduced by using entanglement swapping and/or teleporting quantum states to set up operations on pairs of quantum systems that use entanglement.

A particular entanglement graph may be chosen that presents a desired trade off between the increasing physical complexity and reduced efficiency that tends to accompany increasing connectivity on one hand and the increased time and reduced entanglement fidelity that tends to result from reliance on entanglement swapping to extend entanglement and/or quantum teleportation to move quantum states.

In some embodiments the entanglement graph is a non-planar graph. A graph is non-planar if it cannot be drawn in a plane so that no two edges cross.

In some embodiments the entanglement graph is a regular graph. A regular graph is a graph each vertex has the same number of neighbors; i.e. every vertex has the same degree or valency. A first vertex is a neighbor of a second vertex where the first and second vertices are connected to one another by an edge. Providing a network that has a topology defined by a regular graph can be advantageous because edges of a distance regular graph are distributed over the whole graph. This is advantageous for cases when entanglement needs to be generated on arbitrary pairs of quantum systems that could correspond to vertices located anywhere in the graph.

In some embodiments the entanglement graph is a distance regular graph. A distance regular graph is a regular graph such that for any two vertices a and b, the number of vertices at distance i from a and at distance j from b (where distance between any two vertices of the graph is measured by the shortest route between the two vertices travelling only along edges of the graph) depends only upon i, j and the distance between a and b. A distance regular graph can be advantageous because a network having a topology defined by a distance regular graph can be implemented in ways that use a relatively small number of switches while minimizing the maximum number of entanglement swaps needed to entangle quantum systems of any two nodes.

In some embodiments no connected subset containing Q vertices of the entanglement graph (where Q is an integer that is larger than 2) for which pairs of the vertices of the subset are connected to one another by at least 2 or 3 or 4 edges of the graph (where “connected subset” means that there is a path between any pair of the Q vertices of the subset that follows only edges of the entanglement graph which connect pairs of vertices of the subset) is better connected than any other connected subset containing Q vertices of the entanglement graph that satisfies the same criteria. Here, a first subset is “better connected” than a second subset if there are more edges joining distinct pairs of vertices of the first subset than there are joining distinct pairs of the vertices of the second subset.

In some embodiments the entanglement is a regular graph or distance regular graph that has been modified by adding edges to create one or more subsets of the vertices of the entanglement graph that each include at least 3, 4, 5, or more vertices and have greater connectivity than the same subset of vertices in in the original entanglement graph. In some embodiments the entanglement graph is modified so that the one or more subsets are fully-connected (i.e. to have all-to-all connectivity within the subset). Such embodiments may be beneficial, for example, in cases where it is efficient to execute a quantum informatics program in a way that utilizes multiple entanglements between different pairs of the subset of vertices.

In some embodiments the modified entanglement graph is described by one or more of the following:
the added edges make up a relatively small proportion of the edges of the modified entanglement graph (where “relatively small proportion” means. not more than 30% or 20% or 10% or 5% or 3% or 2% or 1% or 0.5%);
the number of edges joining pairs of vertices in subsets of vertices in the modified entanglement graph that are fully-connected make up a relatively small proportion of the edges of the modified entanglement graph;
the number of vertices belonging to any one fully-connected subset of the vertices of the modified entanglement graph makes up a relatively small proportion of the vertices of the modified entanglement graph; and/or
the number of vertices belonging to all fully-connected subsets of the vertices of the modified entanglement graph taken together make up a relatively small proportion of the vertices of the modified entanglement graph.

In some embodiments an entanglement graph has the form of a regular graph or distance regular graph that has been modified by adding additional vertices. In some embodiments, each of the additional vertices is connected to one vertex of the entanglement graph by a single edge. In some embodiments the added vertices make up a relatively small proportion of the vertices of the modified entanglement graph.

Where a network has a topology that corresponds to a distance regular graph, the number of entanglement swaps required to entangle qubits associated with any two nodes may be fixed. The magnitude of the fixed number depends on the distance of the distance regular graph. The distance of a distance regular graph is the maximum, for all pairs of vertices in the graph, of the number of edges that belong to the shortest path connecting each pair of vertices of the graph.

In some embodiments the entanglement graph is a strongly regular graph. A strongly regular graph is a regular graph with v vertices and degree K that satisfies the conditions that there exists integers λ and μ such that:
Every two adjacent vertices (i.e. joined by an edge) have A common neighbours (i.e. joined by a respective edge to each of the two adjacent vertices); and,
Every two non-adjacent vertices (i.e. not joined by an edge) have μ common neighbours.

The properties of a strongly regular graph can be summarized by (v, k, λ, μ) where v is the number vertices, k is the number of edges connected to each vertex, λ is the number of common neighbours for adjacent vertices and u is the number of common neighbours for non-adjacent vertices. Strongly regular graphs have the advantage of offering good connectivity while minimizing the maximum number of edges between any two vertices.

As will be appreciated, some departure from regularity can be accommodated. The term “regular” as applied to an entanglement graph includes both entanglement graphs that are mathematically regular (i.e. satisfy the precise mathematical definition of regularity) and entanglement graphs that are mathematically regular except for minor deviations from regularity that do not significantly affect functionality. For example, inclusion of one or more dangling vertices (vertices connected to the rest of the entanglement graph by a single edge) or not implementing a minor number of edges of the entanglement graph may be minor deviations from regularity. In some embodiments the entanglement graph is almost regular. A graph that is almost regular may be derived by starting with a regular graph and one or both of: removing one or more vertices and edges that connect to the removed vertices; and adding one or more vertices and at least one edge that connects each of the added vertices to at least one other vertex of the graph. The resulting graph is “almost regular” if the numbers of removed and added vertices are each less than 30% or 22% or 20% or 12% or 5% or 3% of the total number of vertices in the original regular graph.

In some embodiments the graph is a graph that is almost a distance regular graph or almost a strictly regular graph.

In some embodiments the graph is a portion of a regular graph, a distance regular graph, a strictly regular graph that is not all-to-all connected. In some such embodiments the portion of the graph is non-planar.

In some embodiments the entanglement graph has the form of a generalized quadrangle graph.

Examples of particular forms of entanglement graph that are provided by some embodiments include:
entanglement graphs that are distance-regular, for which the variance of the average distance of all nodes to node i is 0 for all nodes;
entanglement graphs that are distance-regular for which the variance of the average distance of all nodes j to node i given by:

$${S}^{2} = \frac{{\sum }_{i , j \neq i} {( {d}_{ij} - \overline{{d}_{ι j}} )}^{2}}{n - 1}$$

where S² is the variance, dᵢⱼ is the distance between nodes i and j, d̅ᵢ̅ⱼ̅ is the average distance from node i to all other nodes j and n is the total number of nodes does not exceed 0.05 or 0.1 or 0.2 or 0.3. The variance may result from hardware specific variability (e.g. quantum systems that will not support a qubit, broken communication channels, quantum systems with different connectivity based on their specialized purposes).
entanglement graphs that are distance-regular, and to which extra quantum systems are connected via an edge to a single quantum system in the distance-regular graph (e.g. to facilitate external communication in/out of the quantum network.

The optimum choice of topology for an entanglement graph may depend on the number of nodes that are to be included in a network (i.e. the number of vertices in the entanglement graph). All-to-all connectivity may be most desirable for a network that has a relatively small number of nodes. As the number of nodes increases, a number of nodes may be reached where it becomes optimum (e.g. for reasons of performance and/or cost and/or reliability) to configure the network to have an entanglement graph that has a topology in which some vertices are not connected by edges but entanglement can be created between any two vertices by at most one step of entanglement swapping (e.g. for any two vertices in the graph there is at least one path between the two vertices that includes only two edges). As the number of nodes in the network is increased further a number of nodes may be reached at which it becomes optimum to use entanglement graphs that have topologies that may require up to 2, 3, 4, or more steps of entanglement swapping to create entanglement between quantum systems belonging to certain pairs of different nodes in the network. Such topologies may have a significantly smaller number of edges per vertex than would be required to provide all-to-all connectivity among the same nodes.

The particular number of nodes at which a certain topology for an entanglement graph becomes optimum is highly dependent on factors such as desired performance metrics for the network, the nature of the quantum systems of the network, the lossiness of optical paths in the network, the technologies used to implement components such as optical switches, BSAs, and so on.

In some embodiments a system includes a number of nodes which may be configured in different ways to form networks that have different topologies. Different configurations may correspond to different connectivity of the nodes to BSAs. For example, in a first configuration all of the nodes may be included in a first network. In a second configuration a subset of the nodes may be configured to provide a second network that has fewer nodes than the first network. In an optional third configuration a different subset of the nodes may be configured to provide a third network that has fewer nodes than the first or second networks. In this example, the first second and third networks may have entanglement graphs that have different types of topology. For example:
A ratio of: a number of edges per vertex for the entanglement graph of the first network to N−1 (where N is the number of nodes in the first network) may be smaller than the same ratio for the second network or the third network.
The first network may not be all-to-all connected while at least one of the second and third networks may be all-to-all connected.

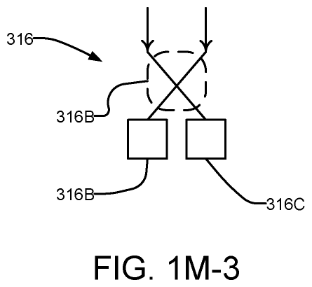

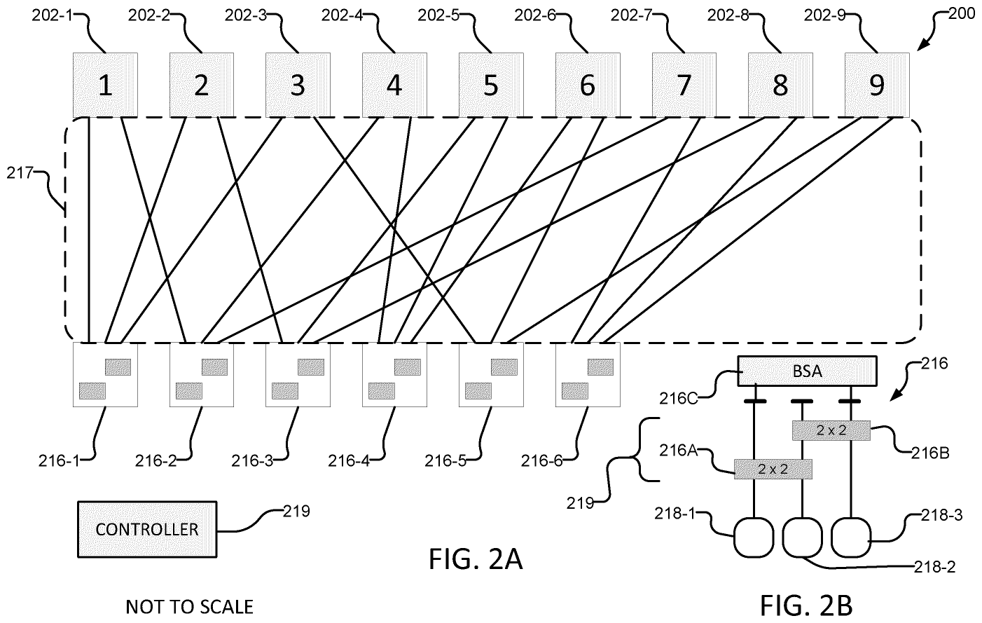

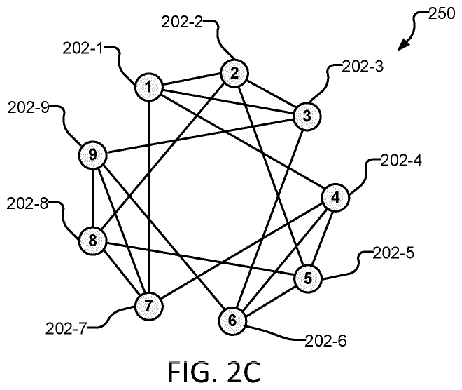

FIG. 2C shows an example entanglement graph 250 that has nine vertices (each represented by one of the circles numbered 1 to 9 in FIG. 2C). Each straight edge in FIG. 2C joins two vertices and represents a direct entanglement path (e.g., entanglement path). For example, node 1 is joined by an edge to nodes 2, 3, 4 and 7 respectively. This means node 1 has shared access to a particular detector unit with each of nodes 2, 3, 4 and 7.

Graph 250 is an example of a non-planar graph. Graph 250 is also an example of a regular graph. Graph 250 is also an example of a strongly regular graph. Graph 250 is also an example of a distance regular graph.

For example, graph 250 shown in FIG. 2C is a strongly regular graph of (9, 4, 1, 2) because there are nine vertices, each vertex is joined by four edges to four other vertices, every two adjacent vertices have 1 common neighbor, and every two non-adjacent vertices have 2 common neighbours. Graph 250 is also known as a Paley graph of order 9. Another example entanglement graph is a strongly regular graph of (243, 22, 1, 2) with 243 vertices which is known as the Berlekamp-van Lint-Siedel graph.

The type of connectivity represented by graph 250 has the advantage of allowing any pair of nodes in quantum network 200 that are not connected by an edge of graph 250 to be entangled using one entanglement swap step while keeping the number and complexity of switches low. It may also be possible to create the same entanglement using more entanglement swap steps.

A graph for defining a network topology may be selected to have a desired number of vertices for the intended application and to have edges which connect the vertices in a way that achieves a desired balance between factors that include: saving cost, reducing switching hardware complexity, in the case of a photonic network, reducing photon loss in the network, and maintaining high entanglement fidelity. The choice of graph can affect parameters such as the number of hardware elements (e.g. switches, BSAs) needed to implement a quantum network that corresponds to the graph; the maximum number of entanglement swaps sufficient to entangle nodes corresponding to any two vertices of the graph; and number of entanglement attempts that can be performed in parallel. Cost, physical size and complexity of network hardware may be reduced by selecting a graph that has fewer edges.

### Nodes

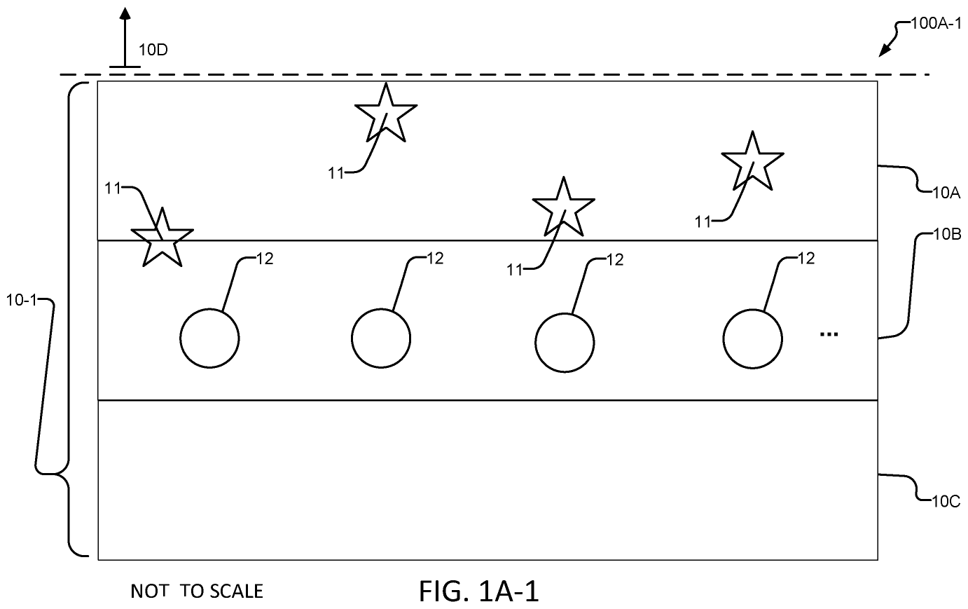

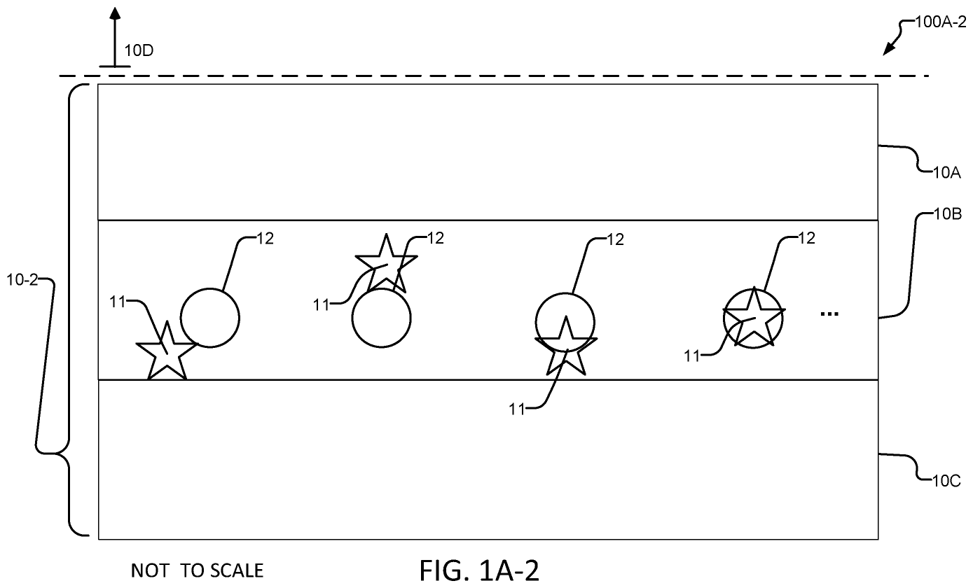

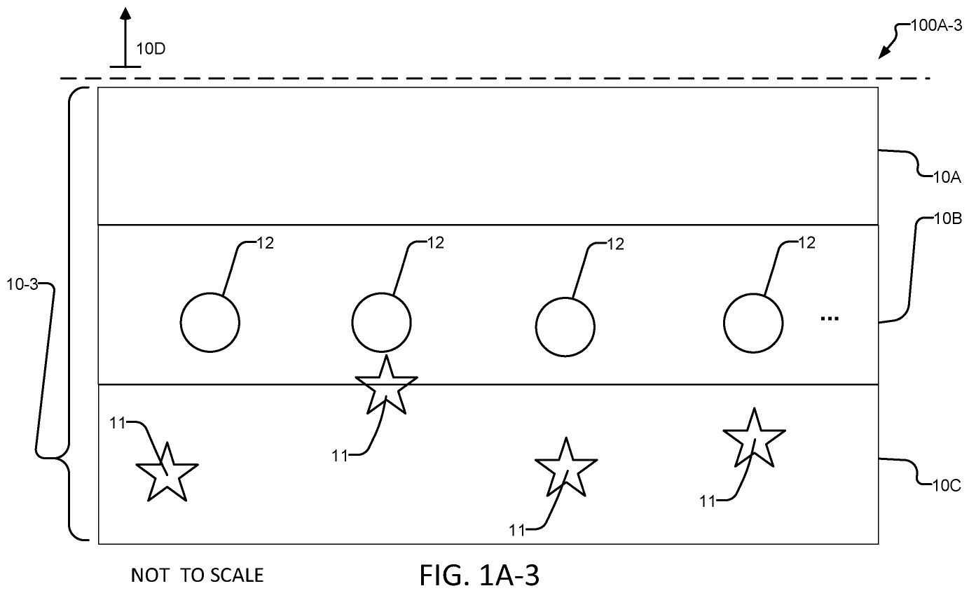

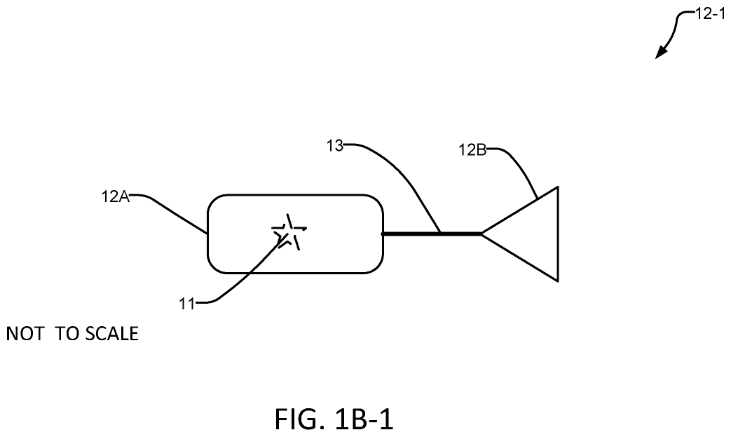

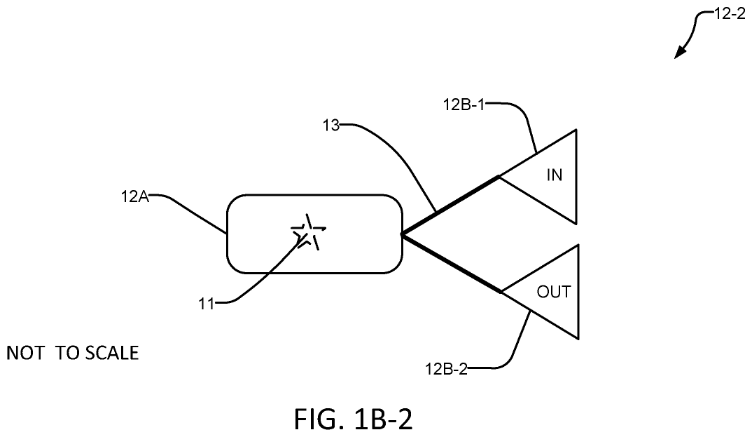

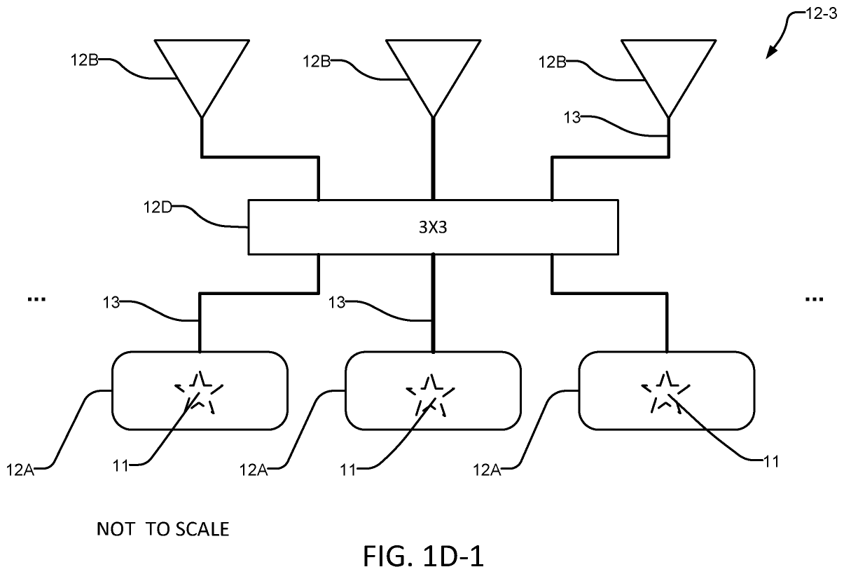

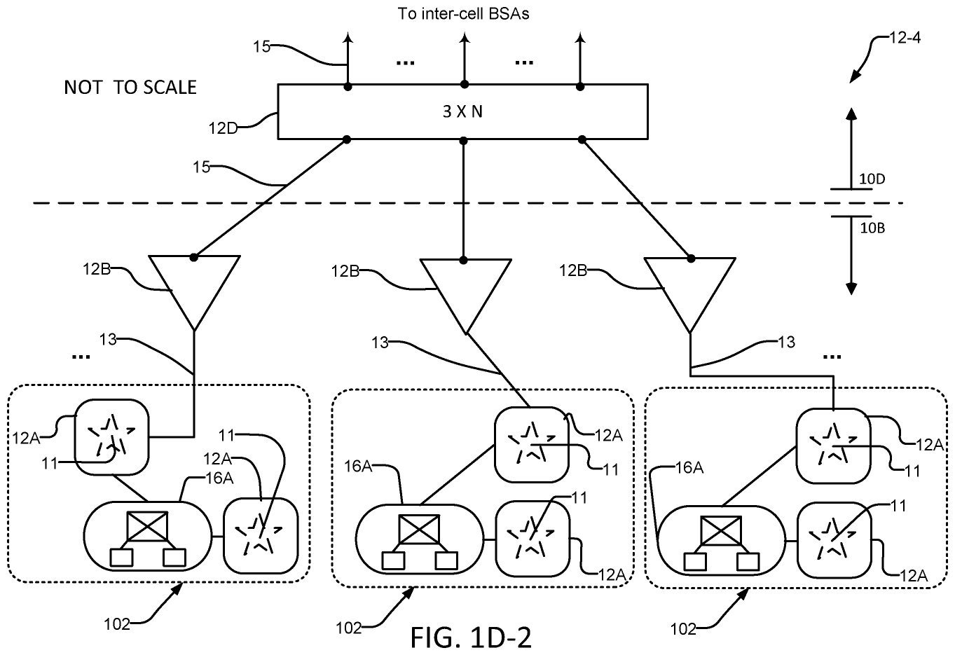

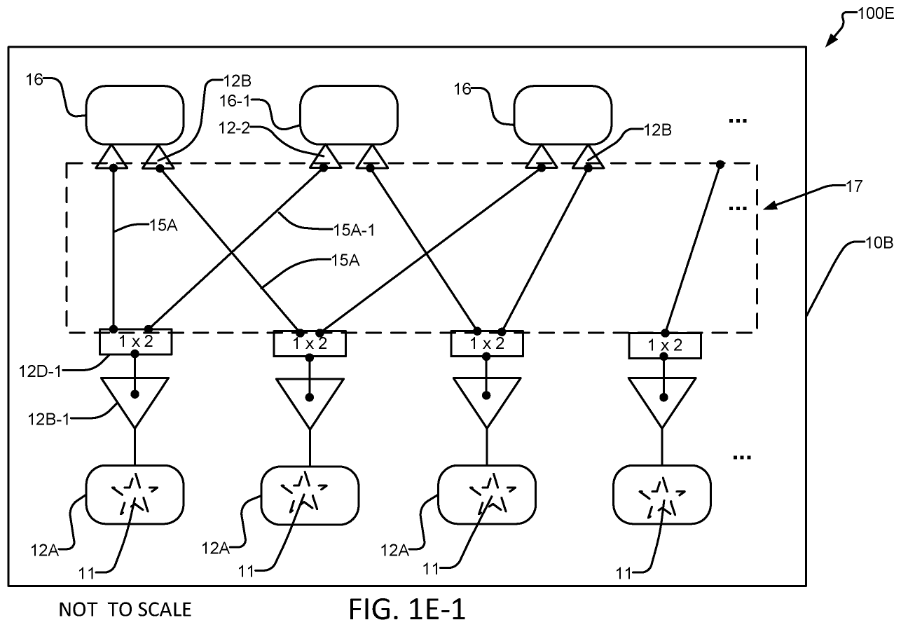

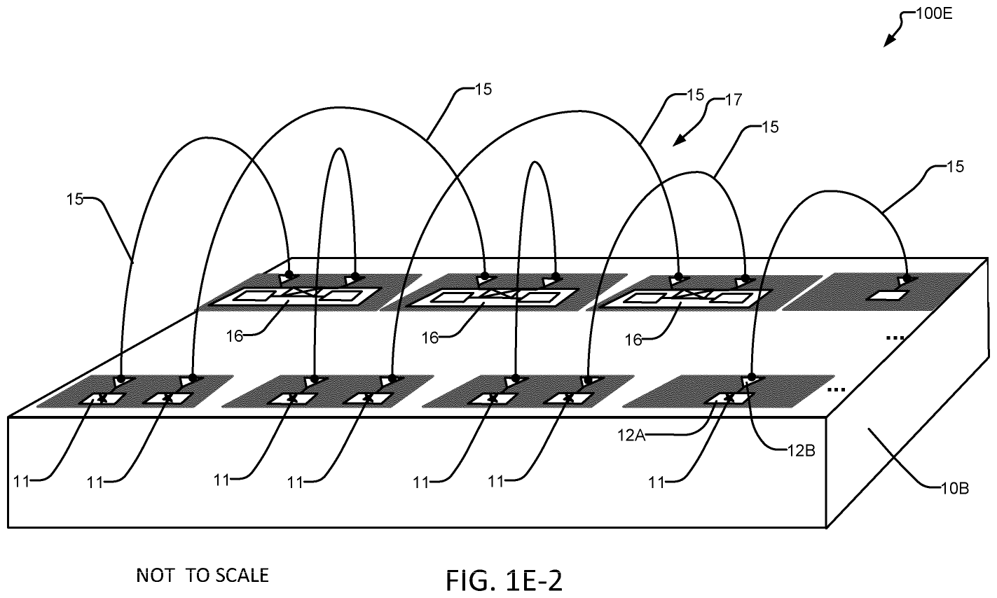

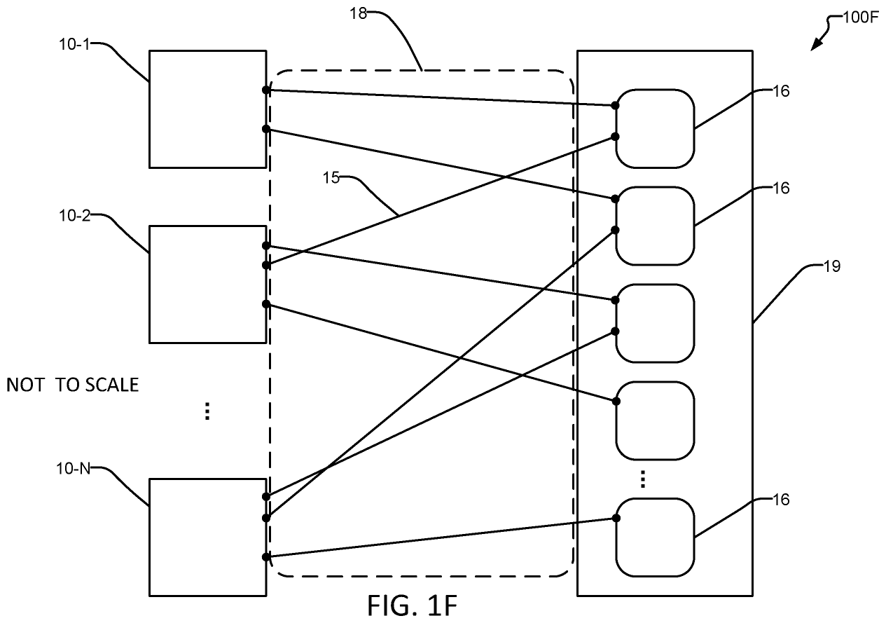

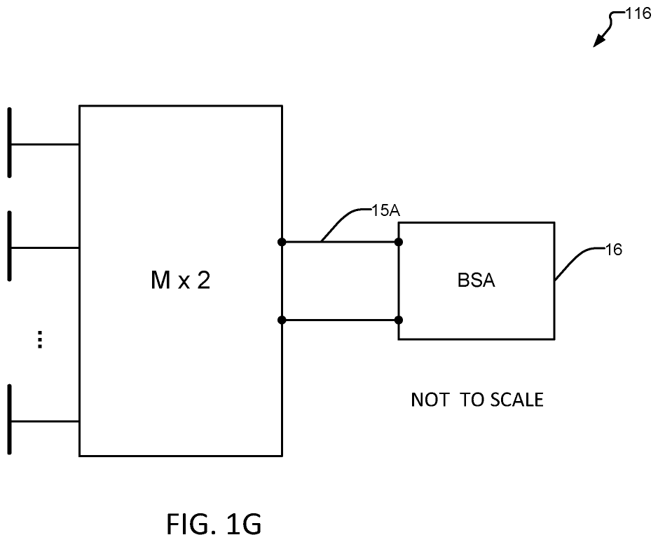

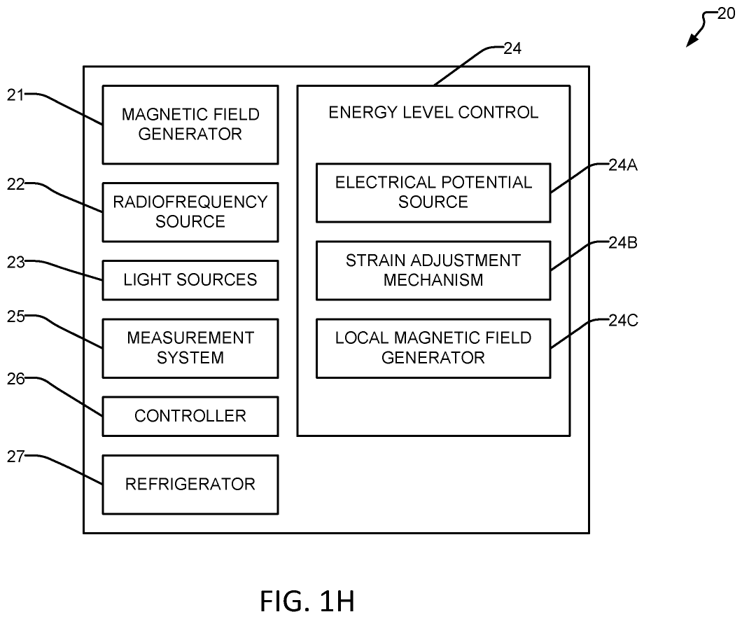

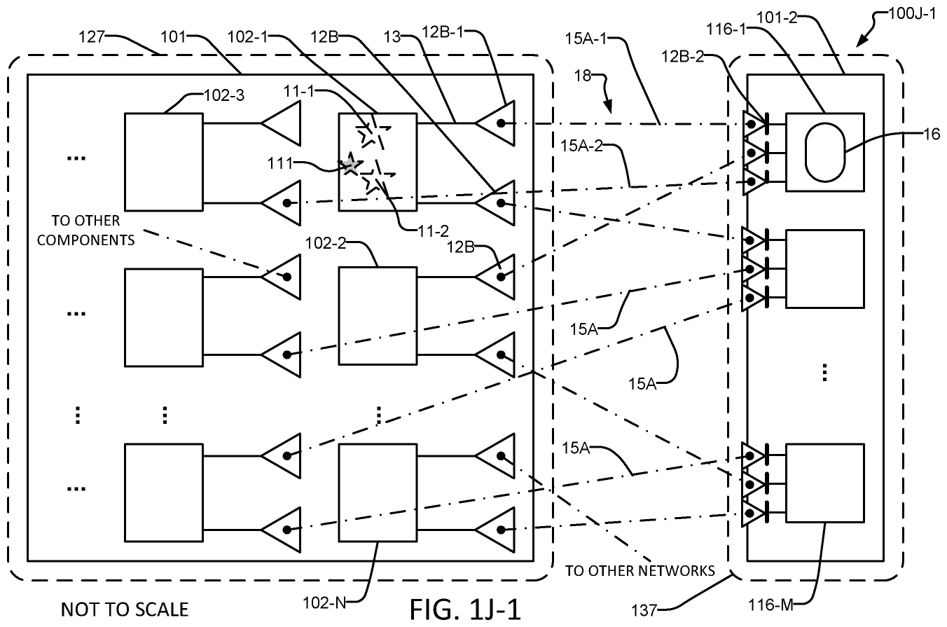

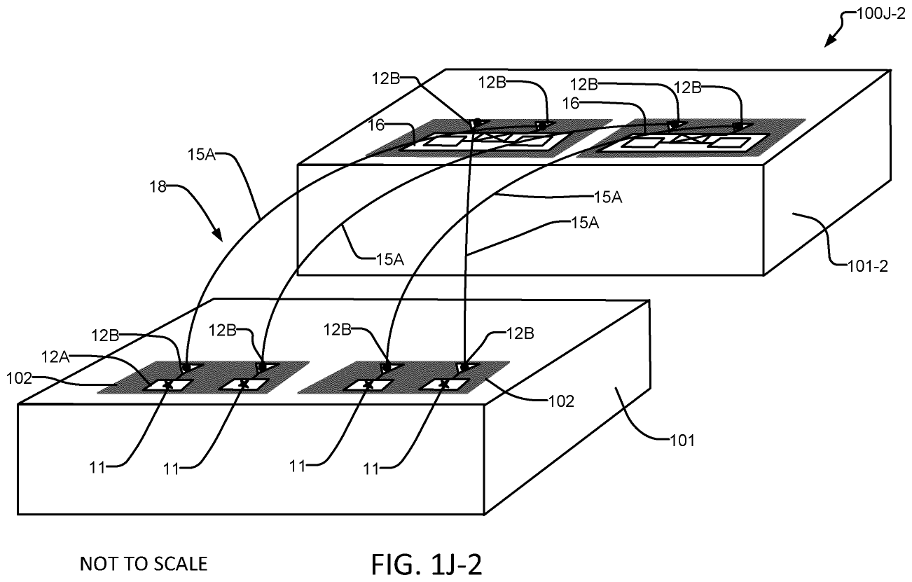

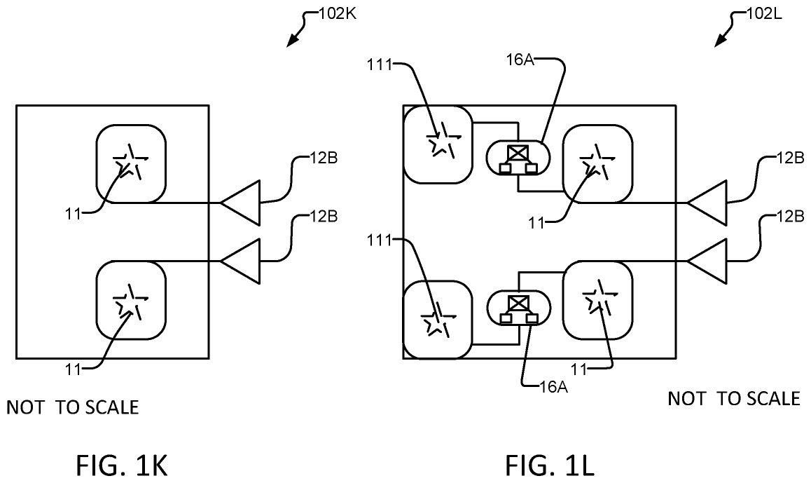

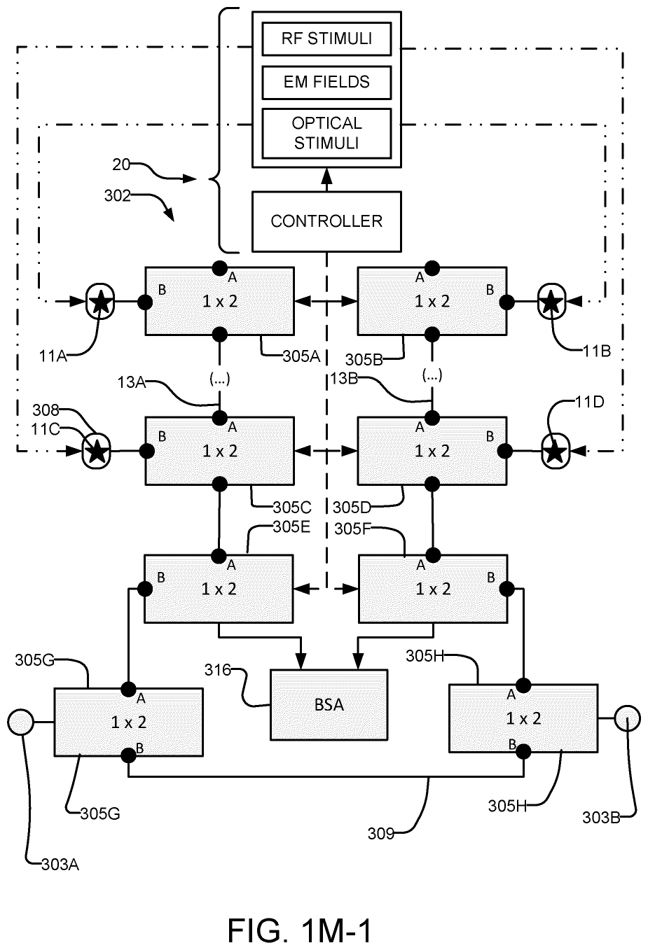

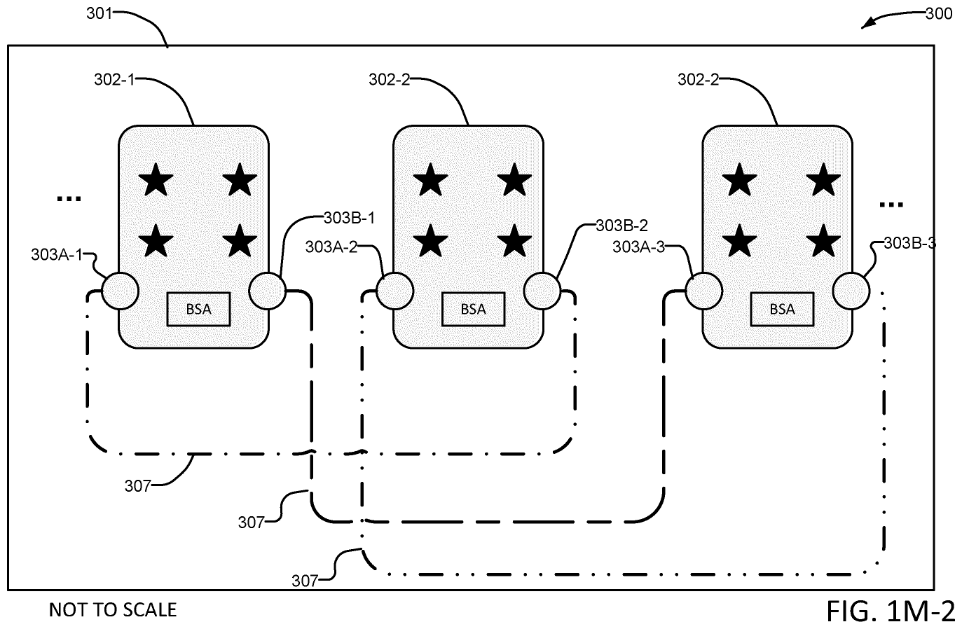

Nodes of a quantum network may have various constructions that accommodate one or more quantum systems. Each node comprises one or more quantum systems. In some embodiments a node comprises a single quantum system that supports a qubit state. In other embodiment, a node comprises a plurality of quantum systems that can each support a qubit state. For example, a node may comprise one or more luminescent centers in a substrate that can each be configured to store one, or two, or more qubit states. In some embodiments nodes are more complicated (see, for example, FIG. 1M-1).

Preferably each node includes a plurality of quantum systems such that at least a first one of the quantum systems of a first node may be used to store a quantum state representing information and simultaneously, a second one of the quantum systems of the node may be entangled with a quantum system of a second node to facilitate an interaction between the first quantum system of the first node and a quantum system of the second node.

Nodes may be structured in various ways depending on the number of and type(s) of quantum systems in each node. The nodes of a quantum network may all have same structure or some nodes may have structures that are different from the structures of other nodes in the network.

In addition to quantum systems each node may include a number of ports that may be used to facilitate entanglement between a quantum system of the node and a quantum system of another node. A node may include one or more switches operable to selectively establish connections by way of which quantum systems of the node may be entangled with other quantum systems within and/or or outside of the node and/or by way of which such different quantum systems may interact with one another.

A node may include mechanisms for: selectively interacting with individual quantum systems of the node, causing interactions between quantum systems of the node, and/or altering properties of individual quantum systems of the node. These mechanisms can take different forms depending on the nature of the quantum systems of the node.

For example, a node may comprise a structure that includes two or more intrinsic spins that can store quantum information and a coupler that facilitates optical interactions between the quantum systems of the node and quantum systems of other nodes. The structure(s) that provide(s) the quantum systems of a node may, for example comprise luminescent centers in a crystalline material. The luminescent centers may, for example comprise T, G, I or M centers in silicon or NV centers in diamond. A T center includes an electron spin and one or more nuclear spins. In some embodiments each node comprises a T center.

In some embodiments a node comprises two or more quantum systems that are each operable to store quantum information (e.g. information in the form of qubits or qudits) together with mechanisms for entangling quantum states of two or more of the quantum systems of the node that is reliable (e.g. each time the mechanism attempts to generate entanglement of the quantum system a probability of successfully generating the entanglement is at least 47%. In some embodiments a probability of successfully generating the entanglement is at least 95%).

In some embodiments quantum systems of some or all pairs of quantum systems of the node are coupled in such a manner that a deterministic entanglement protocol may be applied to generate entanglement of the pair of quantum systems. In such cases the probability that entanglement of the pair of quantum systems will be generated each time the deterministic entanglement protocol is executed can approach 100% (e.g. 95% or better likelihood of success). The coupling between the pairs of quantum systems may be achieved, for example, by placing the quantum systems of a pair in close physical proximity, hyperfine coupling of the quantum systems, optically coupling the quantum systems of a pair to the same optical resonator, and/or providing low-loss optical connections between a pair of the quantum systems of the node.

In some embodiments, some or all nodes include at least one pair of quantum systems that are closely coupled together with mechanisms for performing: deterministic entanglement protocols, deterministic entanglement swap operations and/or Bell state measurements on the at least one pair of closely coupled quantum systems. In such embodiments, a pair of the closely coupled quantum systems may be used to mediate an entanglement swap

In some embodiments, optical connections external to nodes are lossier than optical connections internal to nodes by a factor of at least 2 or at least 5.

In some embodiments, each node includes one or more optical ports by way of which photon states may be received from and/or delivered to components of a quantum network outside of the node (e.g. other nodes, BSAs, and/or optical switches that are external to the node). In some embodiments, nodes integrate one or more of: measurement systems (e.g. photon detectors, BSAs) and optical switches. In some embodiments, the quantum systems of a node are local to one another. For example, the quantum systems of the node may be formed on one substrate or on an area of a substrate that is dedicated to the node. In some embodiments, the quantum systems of each node are separated by distances not exceeding 5 cm or 2 cm or 1 cm or 2000 microns or less. In some embodiments the efficiency of photon transmission within individual nodes is higher than the efficiency of photon transmission between a node and a component (e.g. a BSA or another node) that is external to the node. For example, intra-node optical paths may exhibit photon loss that is significantly less than external optical paths (e.g. by a factor of at least 2 or 10 or more).

In some embodiments nodes include mechanisms for applying quantum gates to two quantum systems within the same node that are more efficient (less likely to fail) than mechanisms provided for applying similar quantum gates to two quantum systems located in different nodes. For example, nodes may include mechanisms for intra-node BSMs that are deterministic or probabilistic with a relatively low probability of failure while mechanisms for inter-node BSMs may be probabilistic with a greater likelihood of failure.

### Example Constructions for Quantum Networks

Quantum networks having topologies as described herein may be implemented using a wide variety of hardware. Any given entanglement graph may be realized using any of a wide variety of hardware that is compatible with the entanglement graph (i.e. the hardware provides nodes that can be mapped to vertices of the graph, and an entanglement mechanism operable to directly entangle quantum systems of each pair of the mapped nodes that correspond to vertices joined by an edge of the entanglement graph, where the entanglement mechanism is not operable to directly entangle those pairs of the mapped nodes that correspond to vertices that are not joined by an edge of the entanglement graph). In this embodiment, the entanglement mechanism is said to be exclusively operable to directly entangle quantum systems of each pair of the mapped nodes that correspond to vertices joined by an edge of the entanglement graph. The possible hardware arrangements may differ in areas: such as the nature of the physical quantum systems that are used to store and manipulate quantum information; the nature of the apparatus and processes used to create entanglement among quantum systems of the quantum network; the nature of the entanglement mechanism used to enable entanglement of specific pairs of quantum systems.

Some hardware networks that may be used to implement networks as described herein may be described as including both stationary qubits and travelling qubits. Stationary qubits are quantum systems that are operable to store quantum information and have a location that is fixed or confined to a node. Travelling qubits are quantum systems that can carry quantum information and are movable. Photons, trapped ions that are shuttled along a shuttle path and quantum dots that are movable along shuttle paths are examples of travelling qubits.

For example, in various embodiments:
electron spins or nuclear spin have the role of stationary qubits while one or more spin-entangled photons have the role of travelling qubits.
superconducting qubits (e.g. Josephson junctions) have the role of stationary qubits, while microwave photons or optical photons generated via transduction have the role of travelling qubits.
trapped ions may have the role of stationary qubits while photons and/or ions that are shuttled along shuttle paths have the role of travelling qubits.

Travelling qubits may be used to generate entanglement among stationary qubits. The choice for mechanisms that define paths along which travelling qubits can move depend on the nature of the travelling qubits. For example, photons may propagate on waveguides such as optical fibers, integrated waveguides etc. as well as via free space paths. Trapped ions and certain types of quantum dots may be shuttled along shuttle paths. The specific mechanisms that may be provided for generating entanglement depend on the natures of the travelling and stationary qubits and their interactions.

In some embodiments, the same quantum system may serve as both a travelling qubit and a stationary qubit. For example, two qubits located in the same node may be entangled. Subsequently, one or both of the entangled qubits may be transported. After the transportation, the two entangled qubits may be located in different nodes. In this example, the two qubits can serve as stationary qubits before and after the transportation. Either or both of the two qubits may serve as a travelling qubit as it is being transported. The qubits may, for example comprise quantum dots or trapped ions.

For example, suppose that it is desired to create the situation where a quantum system in a first node is entangled with a quantum system in a second node. One way to achieve this is to start with both quantum systems at the first node, entangle the quantum states of the quantum systems, and then move one or both of the quantum systems so that the entangled quantum systems are located at the first and second nodes respectively. Depending on the nature of the quantum systems, achieving entanglement of the quantum systems may be achieved by applying quantum gates to the quantum systems (for example, with the quantum systems in a Z-eigenstate, applying a Hadamard gate to a first one of the quantum systems followed by applying a CNOT operation to the quantum systems that is controlled by the quantum state of the first quantum system and has a target of the second quantum system. These operations may be deterministic. While the entanglement is being generated the first and second quantum systems may be strongly coupled. Another example way to create entanglement of the first and second quantum systems is to perform a measurement on the first and second quantum systems that projects into an entangled state (e.g. performing a Bell state measurement on the first and second quantum systems).

Another option is to use the entangled first and second quantum systems as ancilla quantum systems to perform a teleported CNOT gate to entangle the quantum state of a third quantum system at the first node with a fourth quantum system at the second node. This may be done, for example, by applying two qubit gates between the first and third quantum system (at the first node) and between the second and fourth quantum systems (at the second node) followed by measurements of the first and second quantum systems and single qubit operations performed on the third and fourth quantum systems as known in the field.

Two or more quantum systems may be brought together at a location (e.g., a common location) where the quantum systems may be entangled by transporting the quantum systems from other locations via suitable shuttle paths. Quantum systems may be shuttled among nodes using the shuttle paths as required.

In some embodiments, multipartite entangled states (e.g. GHZ states) are distributed among nodes by approaches analogous to the above. For example, three quantum systems may be entangled at a first node and then transported so that the entangled quantum systems are distributed among two or three nodes. As another example, quantum states of one, two or all of the three entangled quantum systems may be teleported to other nodes to achieve the same effect.

The following example describes a quantum network that corresponds to entanglement graph 250 of FIG. 2C. FIG. 2A is a schematic illustration of an example optical quantum network 200 according to another example embodiment. Network 200 comprises a plurality of nodes 202 numbered 202-1 to 202-9. In a preferred embodiment each node 202 comprises a plurality of quantum systems.

Network 200 comprises a plurality of photon detector units 216-1 to 216-6 (collectively and generally 216). Each detector unit 216 comprises at least one BSA 216C and optical switches 217 that are configurable to selectively connect any two input ports of the detector unit 216 to first and second input ports of a BSA 216C of the at least one BSA to allow a Bell state measurement to be made on photon states originating from nodes 202 corresponding to the two input ports of the detector unit 216.

FIG. 2B shows an example construction for detector units 216. In this example, each detector unit has three input ports 218-1, 218-2 and 218-3 (collectively and generally input ports 218) and a switching network 219, which in this example includes switches 216A and 216B, that is operable to couple any of the three possible pairs of input ports 218 to BSA 216C.

Switching network 219 may, for example, comprise two 2×2 switches 216A, 216B coupled to a BSA 216C so that any pair of input ports 218 of the photon detector unit 216 may be coupled to input ports of a BSA by choosing appropriate states of 2×2 switches 216A, 216B.

The plurality of nodes 202-1 to 202-9 are coupled to the plurality of detector units 216-1 to 216-6 by optical paths 217. Optical paths 217 may, for example, comprise optical waveguides (e.g. optical fibers or integrated optical waveguides), free space transmission of photons or combinations thereof. Some or all of optical paths 217 are optionally provided by a fiber braid or knot as described elsewhere herein.

In quantum network 200 each node 202 comprises two ports which are coupled to different detector units 216. Each of the ports is coupled by an optical path 217 to one input port 218 of a corresponding one of detector units 216. For example, node 202-1 is coupled to detector unit 216-1 and detector unit 216-2. In other embodiments each node 202 may comprise a three or more ports and consequently may be coupled to three or more different detector units 216.

In quantum network 200 each detector unit 216 is coupled to three distinct nodes 216. For example, detector unit 216-1 is coupled to nodes 202-1, 202-2 and 202-3. In other embodiments detector units 216 may have other numbers of ports and consequently be coupled to other numbers of nodes 202.

Quantum network 200 includes a controller 219 that is operable to control quantum network 200 to perform desired quantum informatics processing. Controller 219 may, for example, control: initialization of quantum systems of network 200, entanglement of quantum systems of network 200, application of quantum gates to quantum systems of network 200, making measurements of quantum states of quantum system 200, and so on.

During operation of quantum network 200, quantum systems of node 202-1 and node 202-2 can be entangled directly because node 202-1 and node 202-2 are both coupled to the same detector unit 216-1. Specifically, a photon state generated from node 202-1 and a photon state generated from node 202-2 can each travel to detector unit 216-1 where a Bell state measurement may be performed on the photon states. It can also be said that nodes 202-1 and 202-2 share an “entanglement path”.

Likewise, quantum systems of node 202-1 and node 202-3 may also be directly entangled because both node 202-1 and node 202-3 are coupled to detector unit 216-1. Similarly, quantum systems of node 202-2 and node 202-3 are also directly entangle-able because both node 202-2 and node 202-3 are coupled to detector unit 216-1. Applying the same logic, one or more quantum systems of node 202-1 is also directly entangle-able with quantum systems of nodes 202-4 and 202-7 because nodes 202-1, 202-4 and 202-7 are all coupled to detector unit 216-2.

On the other hand node 202-1 does not share an entanglement path with any one of nodes 202-5, 202-6, 202-8 and 202-9. Consequently, to facilitate entanglement between a quantum system of node 202-1 and a quantum system of any one of nodes 202-5, 202-6, 202-8 and 202-9 quantum network 200 may perform entanglement swapping.

Where two nodes are not directly entangle-able, one or more other nodes may be used to mediate entanglement swapping between the two nodes for which entanglement is desired. Where the mediating node is directly entangle-able with both nodes, the entanglement swapping may be conducted via a single step of swapping by the mediating node. For example, in quantum network 200 entanglement between node 202-1 and node 202-5 may be mediated by any one of nodes 202-2, 202-4 and 202-7 with only one step of swapping because every one of nodes 202-2, 202-4 and 202-7 is directly entangle-able with both node 202-1 and node 202-5.

For example, to entangle a quantum system of node 202-1 and a quantum system of node 202-6 network 200 could create entanglement between a quantum system of node 202-1 and a quantum system of node 202-4 and also create entanglement between a quantum system of node 202-6 and a quantum system of node 202-4 and then swap the entanglement to be between the quantum systems of nodes 202-1 and 202-6.

In network 200 and other networks it is possible to move a quantum state from one node to another node by quantum teleportation. This may be used in lieu of (or in combination with) entanglement swapping. For example, consider the case where it is desired to perform a two-qubit operation on first and second quantum states that are respective states of first and second quantum systems, which are associated with a respective first and second nodes 202 that are not directly entangle-able (for example the first node may be node 202-1 and the second node may be node 202-5). Network 200 may be controlled to transfer the second quantum state from the second node (e.g. 202-5) to a quantum system of a third node (e.g. node 202-2) that is directly entangle-able with the first node (e.g. 202-1). After this has been done the operation may be performed using the entanglement created between quantum systems of the first and third nodes.

In networks where multi step entanglement swapping may be required, it is also possible to teleport a quantum state from the second node to a third node that is not directly-entangle-able to the first node but which can be entangled with the first node using entanglement swapping.

Teleportation of a quantum state may also be used to avoid nodes that are currently unavailable or have reduced capability or for which connectivity is not available (e.g. because of a configuration of optical switches) for any reason or to move a quantum state to a quantum system that is somehow better than the quantum system on which the quantum state is currently located (e.g. longer decoherence time and/or higher fidelity and/or better connectivity for future operations) or to move a quantum state to a node that is better situated for upcoming operations that involve the quantum state for any reason.

FIG. 1J-1 is a schematic view of another example optical quantum network 100J-1 according to another example embodiment. Quantum network 100J-1 is made up of a plurality of nodes 102-1 to 102-N (generally and collectively nodes 102). Nodes 102 may be the same as one another or different from one another. Nodes 102-1 to 102-N are interconnected with a plurality of BSAs 16.

In quantum network 100J-1, nodes 102 are formed on or in a substrate 101. In some embodiments substrate 101 is a silicon substrate and is preferably a substrate made of isotopically pure (>95%) ²⁸Si.

In some embodiments a plurality of nodes 102-1 to 102-N are fabricated on a single substrate 101. In some embodiments a plurality of nodes 102-1 to 102-N is distributed over a plurality of substrates 101.

In some embodiments system 100J includes a cryogenic chamber 127 which keeps nodes 102 at a desired cryogenic operating temperature.

FIG. 1J-2 is a schematic perspective view of another example optical quantum network 100J-2 made up of a plurality of nodes 102 containing quantum systems 11 optically connected to a plurality of BSAs 16.

In some embodiments, photon detector units 116 are fabricated on a substrate 101-2. A plurality of photon detector units 116-1 to 116-M may be fabricated on substrate 101-2. In some embodiments substrate 101-2 forms a single substrate with substrate 101. In other embodiments substrate 101-2 is separate from substrate 101. In some embodiments photon detector units 116 are fabricated on both substrate 101 and substrate 101-2. In some embodiments (see e.g. FIG. 1J-1), substrate 101-2 and photon detector units 116 operate in a cryogenic chamber 137. In some embodiments cryogenic chamber 137 is the same as cryogenic chamber 127.

Topologies of networks 100J-1 and 100J-2 are determined by the way in which nodes 102 and BSAs 16 are interconnected. In some embodiments the interconnections are provided by integrated optical layers, free space optical paths, optical fibers, and/or other suitable optical waveguides. In some embodiments, optical interconnections between nodes 102 and BSAs 16 are provided by braids 18 made up of light guides 15A as described below. In such embodiments the topology of the network may be altered by switching from a first braid that provides optical interconnectivity corresponding to a first topology and a second braid 18 that provides optical interconnectivity corresponding to a second topology.

FIG. 1K shows an example node 102K. Each node 102K includes one or more quantum systems 11 that are each optically coupled to a corresponding coupler 12B, for example by an optical system 12 as described above. In some embodiments nodes 102 comprise additional quantum systems and optical structures.

FIG. 1L illustrates an example node 102L that includes some number of additional quantum systems 111 that are not directly optically coupled to a coupler 12B. Quantum systems 111 may be of the same type as or different from one another and may be of the same type as or different from quantum systems 11.

Within each node 102L, some or all of quantum systems 111 can each be coupled to interact with one or more of quantum systems 11 of the node. For example, quantum systems 11 and one or more quantum systems 111 may be optically coupled to an intra-node BSA 16A configured to facilitate an entanglement between such quantum systems 11 and quantum systems 111. A node 102L may be constructed in a way which also facilitates coupling of at least some of quantum systems 111 with one another. For example, a pair of quantum systems 111 may both be optically coupled to another intra-node BSA that facilitates entanglement between the pair of quantum systems 111.

In some embodiments one or more quantum systems 111 and one of quantum systems 11 are included in an atomic scale structure within which the quantum system(s) 111 can interact with the associated quantum system 11, for example by way of hyperfine interactions, spin-orbit coupling or the like. In some embodiments quantum systems 111 and/or quantum systems 11 within a node 102 can be entangled deterministically for example by one or more of application of microwave pulses or tuning the overlap of wavefunctions of two quantum systems.

In some embodiments node 102L includes an intra-node system of waveguides 113 arranged to optically couple quantum systems 111 and quantum systems 11 to an intra-node BSA 16 such that quantum systems 111 and/or quantum systems 11 can be entangled using photons and the intra-node BSA 16.

It can be appreciated that, within any node 102, quantum systems 11 and/or quantum systems 111 may be initialized in desired quantum states, the quantum states may be manipulated by applying quantum gates and/or measurements, two qubit gates may be applied to certain pairs of quantum systems of the node 102 etc. Resulting quantum information may be stored in the quantum states of one or more quantum systems 11 and/or quantum systems 111 of the node 102.

A quantum system 11 of one node 102 may be entangled with a quantum system 11 of a different node 102 by a heralded entanglement protocol. The heralded entanglement protocol may comprise causing photon states to be emitted from each of the quantum systems 11 and directing the photon states from nodes 102 to a BSA 16.

A quantum system 11 of a node 102 may be caused to undergo a quantum transition which results in emission of a photon state which is entangled with the quantum state of the quantum system 11. Depending on the initial quantum state of the quantum system 11, the photon state may be a superposition of photon basis states such as a superposition of: a photon is present and a photon is not present; a photon is in a first time bin and the photon is in a second time bin temporally offset from the first time bin; the photon is in a first polarization state and the photon is in a second polarization state orthogonal to the first polarization state, etc.

The resulting entanglement may be consumed to move quantum information about in a network, for example by teleporting the quantum state of a quantum system 111 in one node 102 to another system 111 in a different node 102 and/or to teleport a two-photon gate to operate on quantum systems 111 in different nodes 102. The resulting entanglement may also be transferred within a node 102 from an initially entangled quantum system 11 to a quantum system 111 or a different quantum system 11.

In some embodiments some or all of the quantum systems 11 and 111 of a node 102 are provided by one or more luminescent centers or crystal defects. The luminescent centers may, for example comprise T centers. A T center includes an electron spin and one or more nuclear spins. In some embodiments each quantum system 11 comprises an electron spin of a T center and the additional quantum systems 111 comprise at least one nuclear spin of the T center.

Couplers 12B (schematically depicted as triangles in FIGS. 1B-1E) may be fabricated on silicon substrate 101 to direct single photons into and/or out of nodes 102. In some embodiments couplers 12B are optically coupled to quantum systems 11 by waveguides 13.

In optical quantum network 100J, two couplers 12B each associated with a quantum system 11 are provided for each node 102. In other embodiments a node 102 may comprise a different number of couplers 12B. In some embodiments the number of couplers 12B for each node 102 is in the range of 1 to 100. In some embodiments each node 102 includes the same number of couplers 12B. In some embodiments some or all of nodes 102 have fewer couplers 12B than there are other nodes 102 in the optical network.

In quantum system 100J BSAs 16 are provided in photon detector units 116. In this example, each photon detector unit 116 has three input ports and includes internal switching which is selectively configurable to connect the BSA 16 to perform a Bell state measurement on photon states received at any two of the three input ports. Each of the input ports is optically coupled to a corresponding coupler 12B. A photon detector unit 116 may comprise any suitable number of ports.

There is a synergy when a detector unit 116 is used in a network topology corresponding to an entanglement graph which is not all-to-all connected but includes groups of vertices that are all-to-all connected (e.g. groups of vertices that are connected in triangles) where a number of the input ports of the detector unit 116 matches the number of vertices in the groups of all-to-all connected vertices. An example of a graph which includes groups of vertices connected in triangles is a strongly regular graph characterized by the parameter set (v, k, λ, μ) where v is the number of vertices, k is the number of connections to each vertex, λ is the number of common neighbours for each pair of vertices joined by an edge and μ is the number of common neighbours for non-adjacent vertices where λ=1 and μ=2.

Another example is a distance regular graph having a distance that is greater than or equal to 2 or greater than 2. The distance regular graph may be described by an intersection array {k, b₁, . . . , b_{d-1}; 1, c₂, . . . , c_{d}}. If that intersection array has the form {k, k−2, . . . , b_{d-1}; 1, 2, . . . , c_{d}}, the distance regular graph will include groups of three vertices connected in triangles. Such graphs may be efficiently mapped to a hardware configuration using detector units 116 which have three input ports because doing so requires significantly fewer optical paths and switches for a given degree of connectivity to interconnect nodes and detector units 116 than would be required if every the mapping of each graph edge to hardware included two optical paths to provide connection to a BSA.

In some embodiments each detector unit has a number of ports sufficient to connect to two nodes that correspond to vertices of an entanglement graph that are connected by an edge as well as all common neighbours of those two nodes. In such embodiments each detector unit may have ports that are optically connected to each of two nodes that correspond to vertices connected by an edge and to each one of the common neighbors of the two nodes (where a node is a “neighbour” of another node if the two nodes correspond to vertices of the entanglement graph that are connected by an edge).

Couplers 12B of nodes 102 are each optically coupled to a coupler 12B of a photon detector unit 116 by an optical path 15. For example, light guide 15A-1 couples coupler 12B-1 of node 102-1 to coupler 12B-2 of photon detector unit 116-1. Accordingly a direct optical connection is provided between quantum system 11-1 of node 102-1 and BSA 16 of photon detector unit 116-1. Other light guides 15A are provided to optically couple other pairs of couplers 12B on substrate 101 or 111 or to ports of other optical quantum devices on other substrates.

In quantum networks 100J-1 and 100J-2, light guides 15A may be provided in the form of a fiber braid 18 which defines a particular entanglement connectivity topology between nodes 102. The fiber braid 18 may include one or more optical switches. Such optical switches may operate at room temperature. The entanglement connection topology may be expressed in the form of an entanglement graph as described elsewhere herein in which vertices of the entanglement graph represent nodes 102. Two vertices of the entanglement graph are joined by an edge if a BSA 16 is connected to perform a Bell state measurement on photons received from quantum systems 11 of the nodes associated with the two vertices. For example, in an entanglement graph for optical network 100J, vertices corresponding to nodes 102-1 and 102-3 are joined by an edge because light guides 15A-1 and 15A-2 optically connect quantum systems of each of these nodes to a photon detector unit 116-1 which can be configured to perform a Bell state measurement on photon states originating from these quantum systems. Such a Bell state measurement may be applied in an entanglement protocol to entangle quantum states of the two quantum systems 11.

Optical quantum network 100J may also be operated to direct single photon states from any selected node 102 to any of the photon detector(s) 116 to which the node 102 has a direct optical connection or an optical connection by way of another node 102 (shown as connection “TO OTHER COMPONENTS” in FIG. 1J-1).

FIG. 1M-1 shows an example node 302 according to an example embodiment. FIG. 1M-2 is a schematic illustration of an optical quantum network 300 according to an example embodiment that includes a number of nodes 302. Nodes 302 are depicted as dashed rectangles in FIG. 1M-2. Nodes 302 are fabricated in or on one or more substrates 301

As shown in FIG. 1M-1, each node 302 comprises a plurality of quantum systems 11 (in this example, quantum systems 11A through 11D are shown, additional quantum systems 11 may be provided as indicated by the ellipsis “( . . . )”). Quantum systems 11 are depicted schematically by stars in FIG. 1M-1. Optical quantum network 300 may comprise any suitable number of nodes 302.

At least some of nodes 302 incorporate a BSA 316. Each BSA 316 may, for example include an interference unit 316A. and a pair of single photon detectors 316B and 316C as shown in FIG. 1M-3. Inputs of BSA 316 are optically coupled to quantum systems 11 of the node 302 by waveguides 13A and 13B.

Individual quantum systems 11 or groups of quantum systems 11 may be selectively coupled to or uncoupled from a waveguide 13A or 13B by an arrangement of optical switches 305. For example, FIG. 1M-1 shows optical switches 305A, 305B, 305C and 305D that are respectively operable to couple quantum systems 11A, 11B, 11C and 11D to a corresponding one of waveguides 13A and 13B. Switches 305 are operable to couple either one of quantum systems 11A and 11C to waveguide 13A and to couple either one of quantum systems 11B and 11D to waveguide 13B. In this example, each switch 305 is a 1×2 switch that has a common port (unlabeled) that is selectively connectable to either port A or port B.

The connectivity provided by node 302 allows one of quantum systems 11A and 11C to be entangled with one of quantum systems 11B and 11D by a heralded entanglement protocol that uses the associated BSA 316. The inclusion of BSAs 316 in nodes 302 facilitates “intra-node” entanglement between quantum systems within each node 302. Intra-node entanglement may use low-loss optical paths that are entirely within the node 302.

In some embodiments some or all quantum systems 11 of nodes 302 include a broker quantum system and one or more client quantum systems. The broker quantum system may, for example, comprise a spin that has an optical transition. The one or more client quantum systems may, for example, comprises spins that are coupled to the broker quantum system (e.g. by hyperfine interactions, spin-orbit coupling or other coupling mechanism). For example, the broker quantum system may comprise an electron or hole spin and the client quantum system(s) may comprise nuclear spins. For example, some or all quantum systems of a node 302 comprise a T-center in which an electron spin or hole spin serves as a broker and one or more nuclear spins serve as clients. For example, quantum systems 11-1A through 11-1D may each comprise a T center.

At least some of nodes 302 also comprise one or more optical ports 303 that facilitate optical coupling of quantum systems of the node 302 to other parts of the quantum network (e.g. other nodes, measurement apparatus, BSAs located outside of the node etc.).

In optical quantum network 300, nodes 302 each include a port 303A which can be optically coupled to waveguide 13A (by suitably configuring switches 305G and 305E) and port 303B which can be optically coupled to waveguide 13B (by suitably configuring switches 305H and 305F). Each of ports 303A and 303B may carry incoming photons and/or outgoing photons.

Ports 303-1A and 303-1B may incorporate optical couplers 12B configured to optically couple the corresponding waveguide 13A or 13B to a light path 307 such as an optical fiber or integrated waveguide or free space optical path. Light paths 307 may be provided in the form of a knot or braid as described elsewhere herein.

In node 302 as illustrated in FIG. 1M-1, switches 305G and 305E may be configured to connect port 303A to a first input of BSA 316 and switches 305H and 305F may be configured to connect port 303B to a second input of BSA 316.

Ports 303A and 303B facilitate “inter-node” photon interactions. For example port 303A of node 302-1 may receive a photon emitted by a quantum system 11 of another node 302 and switches 305E and 305G may be set to couple that single photon into the first input of BSA 316 while switches 305H and 305F are configured to direct a single photon from a quantum system connected to waveguide 13B (e.g. quantum system 11B or 11D) into the second input of BSA 316. A heralded entanglement protocol may therefore be executed to generate entanglement of the quantum systems that emitted the single photons.

In some embodiments an optical network includes one or more optical switches connected to allow photons from any of several sources to be delivered to ports 303. For example, each of ports 303 may be connected to an output of a switch (not shown in FIG. 1M-2) that has a plurality of inputs. In some embodiments the switch is on or in substrate 301 and the inputs each connect either to a respective coupler on substrate 301 or to an optical source (e.g. waveguide 13A or 13B). This construction can facilitate selectively coupling photons from off-chip sources to port 303.

In some embodiments one or more ports 303 of a node 302 is each optically connected to a coupler on substrate 301 and an off-chip switch is provided to selectively route photons to the port 303 from various sources by way of the coupler. The switch may, for example comprise a 1×N off-chip switch. A controller 20 as described elsewhere herein may coordinate emission of photons by different quantum systems as required.

In some embodiments one of ports 303A and 303B is designated as an “OUT” port which is used to send single photons to a destination outside of the node and the other one of ports 303A and 303B is designated as an “IN” port which is used to receive single photons from sources outside of the node. In some embodiments one or both of ports 303A and 303B is sometimes used to receive photons from a source outside of the node and is sometimes used to send photons to a source outside of the node.

In some embodiments nodes 302 include an optical switch or switches (e.g. switches as shown in FIGS. 1D-1 and 1D-2) that are selectively configurable to optically connect ports 303A and 303B of a node 302 to one another such that a photon received at one of ports 303A and 303B will be passed to the other one of ports 303A and 303B. This configuration may be used to extend connectivity of network 300 (e.g. by guiding a photon from a source at one node 302 through one, two or more other nodes 302 to a BSA at which a Bell state measurement may be performed on the photon and a photon from another source in network 300).

The design of nodes 302 of network 300 simplifies configuring network 300 to have a topology defined by a hardware graph (i.e. a graph that specifies optical connections between specific components such as quantum systems, optical switches, BSAs etc.) that is compatible with a particular entanglement graph. A particular entanglement graph may be implemented using any of multiple compatible hardware graphs.

An edge between two nodes in an entanglement graph may be provided in a network that includes nodes 302 by connecting an optical fiber between an “out” port of a first one of the nodes 302 and an “in” port of the other one of the nodes 302.

Furthermore, in the case where every node 302 of network 300 may be connected to any other node of network 300 either by direct connection provided by an optical fiber 307 or by an indirect connection that passes through one or more intermediate nodes 302, one has the option of creating entanglement between quantum systems 11 of any two nodes 302 in network 300, even if those nodes are not directly optically connected to one another, in two ways. One way is to route photons along an indirect path and another way is to use entanglement swapping.

A photon from one node 302 may be routed to another node 302 by way of one, two, or more intermediate nodes 302 until reaching a node 302 where a Bell state measurement will be performed on the photon (e.g. by BSA 316). Requiring the photon to pass through the intermediate nodes may increase the probability that the photon will be lost. However, if the photon is not lost and entanglement is achieved then the fidelity of entanglement can be high.

In the intermediate nodes 302, one or more switches (e.g. switches 305G, 305H) may be set to a blocking state in which photons are passed directly between ports 303A and 303B (e.g. via optical path 309). The switches (e.g. 305G, 305H) may block the photons from reaching BSA 316 and waveguides 13A, 13B of the intermediate node 302.

Another option for entangling the same quantum systems 11 is to entangle a number of pairs of quantum systems that form a path between the two quantum systems 11 to be entangled and then extend entanglement to be entanglement of the two quantum systems 11 by entanglement swapping. For example, consider the case where it is desired to entangle first and fourth quantum systems 11 by entanglement swapping. One might entangle the first quantum system with a second quantum system and entangle the fourth quantum system with a third quantum system. One can then cause the first and fourth quantum systems to be entangled. This entanglement swapping may, for example, be done by performing a Bell state measurement between the second and third quantum systems and applying conditional single qubit gates based on the result of the Bell state measurement to the second and third quantum systems. The result is the entanglement between the first and second quantum system and the entanglement between the third and fourth quantum system is consumed to yield the desired entanglement between the first and fourth quantum system.

Where photon loss over an indirect path is high, entanglement swapping may be the faster option. However, each step of entanglement swapping tends to reduce fidelity of the eventual entangled state. Therefore, a network like network 300 may be controlled to more quickly produce entanglement that has lower fidelity by entanglement swapping or to produce entanglement that has higher fidelity by direct entanglement which is potentially slower.

### Other Example Quantum Networks

The physical structures that correspond to edges of an entanglement graph depend on the nature of the quantum systems that are used to store quantum information in a quantum network. One approach that can work to entangle some types of quantum systems involves causing the quantum systems to emit particles such as photons that are themselves entangled with the corresponding quantum system and performing a Bell state measurement on the emitted particles. This approach may be applied, for example, to entangle quantum states of quantum systems comprising electron spins. As described above, a quantum network may include structures (e.g., optical switches, ring resonators, etc.) that define paths that guide the emitted particles to a suitable BSA. In this case an edge of an entanglement graph may correspond to the case where the paths are arranged to allow emitted particles from two nodes to be directed to the same BSA.

Another approach that can work to entangle most types of quantum systems that may be used to store and manipulate quantum information is to bring two of the quantum systems into close proximity (e.g. by “shuttling” one or both of the quantum systems) such that the quantum systems become coupled and applying one or more quantum gates to the coupled quantum systems (e.g. by delivering an appropriate series of electromagnetic pulses of a suitable frequency). Once entangled one or both of the entangled quantum systems may be shuttled along a shuttle path to a desired location (node). A quantum network may include mechanisms for shuttling quantum systems along shuttle paths among nodes. In this case an edge of an entanglement graph that joins first and second vertices may correspond to a physical arrangement of shuttle paths that allow two quantum systems to be placed close together and entangled and then transported via one or more shuttle paths so that one of the quantum systems is at a first node corresponding to the first vertex and the other one of the quantum systems is at a second node corresponding to the second vertex.

Another approach that can work to entangle certain types of quantum systems is to electromagnetically couple the quantum systems using electronic circuits. For example, superconducting qubits such as transmons, can be entangled in this manner. In this case an edge of an entanglement graph may correspond to the case where an electronic circuit is configurable to couple quantum systems associated with two different nodes.

For example, where the quantum systems are provided by trapped ions, vertices of an entanglement graph may correspond to individual ion traps and edges of the entanglement graph may correspond to mechanisms for shuttling ions among the ion traps.

Any of the above structures that can be configured to correspond to an edge of an entanglement graph may be called an “entanglement means”. As will be appreciated, an entanglement means is operable for pairwise entangling quantum systems that are respectively located at different nodes of any of the pairs of the nodes which correspond to vertices of the entanglement graph that are joined by an edge.

One aspect of the invention provides architectures for networks of quantum systems that may be used to process quantum information and related methods. These architectures may be used to provide quantum networks that have topologies as described above as well as other topologies.

These architectures include one or more units. Each of the units supports one or more components of an optical quantum network. Each unit includes optical ports at known locations. Optical paths (e.g. optical fibers) may be coupled to the optical ports. The optical paths may be configured to carry photons between different optical ports of the same unit or between optical ports on different units. Optical connectivity between different components of the optical network is defined at least in part by the optical paths. The optical connectivity may be altered by providing sets of optical paths that connect different pairs of the optical ports.

Collectively the one or more units include quantum systems that are each operable to store and/or manipulate a quantum state, for example a qubit state, in a quantum informatics process, entanglement means (e.g. BSAs), and optical paths. In some embodiments the components include optical switches. Certain interactions between different ones of the quantum systems are mediated by single photons.

Components may be distributed amongst units in many different ways. In some embodiments BSAs and quantum systems which can be optically connected to the BSAs are provided on different units. In some embodiments BSAs and quantum systems that can be optically connected to the BSAs are provided in the same unit. In some embodiments individual nodes are provided on separate units. In some embodiments some or all units incorporate plural nodes.

In some embodiments some or all of the components are formed on substrates (chips). In such embodiments a unit may comprise one or more chips.

Optical ports of the units may comprise optical couplers that are exposed at locations on one or more surfaces of the units. In some embodiments, one or more structures comprising optical components that facilitate transmission of photons in either direction between the exposed optical couplers and optical paths that are external to the unit are engageable with the unit. When the structure(s) are engaged with the unit the structures keep the optical components aligned with the corresponding couplers on the unit. The external optical paths may extend between optical couplers on the same unit, between optical couplers on different units, and/or between optical couplers on one unit and external optical devices. The external optical paths may be defined, for example, by optical fibers and/or free space optics.

In some embodiments each of one or more units 10 comprises one or more nodes (e.g. as described elsewhere herein) and interconnections between different ones of the nodes are provided, at least in part, by the external paths.

FIGS. 1A-1 to 1A-3 are schematic illustrations showing example constructions for a unit 10. In these examples, units 10 have a layered substrate structure. A network 100A may include one or more units 10. In the examples of FIGS. 1A-1 to 1A-3, each unit 10 comprises an integrated device layer 10B, a first adjacent layer 10A adjacent to a first face of integrated device layer 10B, and a second adjacent layer 10C adjacent to a second face of integrated device layer 10B.

Network 100A optionally includes other components not integrated within a unit 10 (i.e. components that are “off-chip”). Possible off-chip components 10D of network 100A (not shown in FIGS. 1A-1 to 1A-3) are indicated by an arrow in FIGS. 1A-1 to 1A-3.

In some embodiments layers 10A, 10B and 10C are of the same material. In some embodiments layers 10A, 10B and 10C are of different materials. In some embodiments layers 10A, 10B and 10C comprise solid state materials such as silicon, diamond or gallium arsenide.

In some embodiments integrated device layer 10B consists primarily of a single material. In some embodiments integrated device layer 10B comprises plural sublayers of different materials.

FIG. 1A-1 is a schematic side view of a unit 10-1 in a network 100A-1 according to an example embodiment. Unit 10-1 includes a quantum system layer formed in first adjacent layer 10A. Quantum systems 11 that may be used as physical qubits are distributed in or on the edge of quantum system layer (first adjacent layer 10A).

The quantum system layer may, for example, comprise a crystalline material such as silicon, gallium arsenide, or diamond. Quantum systems 11 may, for example, be provided by spins associated with luminescent centers in the crystalline material. The luminescent centers may, for example comprise T, G, I or M centers in silicon or NV centers in diamond.

It is not mandatory that quantum systems 11 which act as physical qubits in quantum networks as described herein are of a type that can be caused to emit optical photons. Quantum systems 11 in quantum networks as described herein may emit in other regions of the spectrum (e.g. in the microwave range). In some embodiments such quantum systems are used in combination with a suitable transducer that generates an optical photon state (e.g. in the near infrared) that replicates information from the quantum state of the emission. Entanglement between two such quantum systems may be achieved by an entanglement protocol that includes performing a Bell state measurement on the resulting transduced optical photon states. For example, superconducting Josephson junctions may be used as qubits. Microwave photon states emitted by superconducting qubits may be converted to optical photon states by transduction, for example using apparatus as described in PCT international patent publication WO 2022/020951 which is hereby incorporated herein by reference for all purposes.

In some embodiments quantum system layer comprises crystalline silicon that is isotopically enriched in ²⁸Si (e.g. is made up of 90% or more or 95% or more or 99% or more or 99.5% or more by number ²⁸Si). ²⁸Si is an isotope of silicon for which the nucleus has zero intrinsic spin. In some embodiments unit 10 is part of a silicon on insulator (SOI) structure.

Unit 10-1 includes an integrated optical layer formed in integrated device layer 10B that includes optical structures 12 that are configured to couple individual photons emitted from individual ones of quantum systems 11 into corresponding light guides (e.g. optical fibers). Each optical structure 12 may be adjacent to or in the vicinity of its corresponding quantum system 11.

FIG. 1A-2 is a schematic illustration showing another example embodiment of a unit 10-2 in a network 100A-2. In unit 10-2 quantum system unit layer and integrated optical layer are both formed in the integrated device layer 10B. At least some of optical structures 12 may be formed in close proximity to the corresponding quantum systems 11.

FIG. 1A-3 is a schematic illustration showing another example embodiment of a unit 10-3 in a network 100A-3. In unit 10-3 a quantum system layer is formed in second adjacent layer 10C and an integrated optical layer is formed in integrated device layer 10B.

FIGS. 1B-1 and 1B-2 schematically illustrate example embodiments of an optical structure 12. FIG. 1B-1 is a top view of an example optical structure 12-1 that comprises an optical resonator 12A that is located in close proximity to a corresponding quantum system 11 (shown as dashed star in FIG. 1B-1). Optical resonator 12A has a resonant wavelength that corresponds to an optical transition of the quantum system 11. Optical resonator 12A may, for example comprise a photonic cavity. Optical structure 12 also includes an IN/OUT coupler 12B coupled to optical resonator 12A by a waveguide 13. Coupler 12B is configured to couple photons into or out of an external optical path (e.g. an optical fiber or free space optics (not shown in FIG. 1B-1). A photon emitted when the quantum system 11 undergoes the quantum transition (e.g. as a result of a spin-selective optical cycle) is coupled into optical resonator 12A and delivered to coupler 12B. Coupler 12B couples the emitted photon into a corresponding optical path by way of which the photon can reach an intended destination. The optical path may, for example, comprise an optical fiber and/or an optical path defined by optical elements that cause the photon to travel toward its destination through free space. Coupler 12B may, for example, comprise a grating coupler, a butt coupler, or a fiber wirebonded to waveguide 13. Couplers 12B are distributed at known locations on at least one face of unit 10.

Optical structure 12 may comprise any suitable number of couplers 12B. FIG. 1B-2 shows a top view of another example optical structure 12-2 that is substantially similar to optical structure 12-1 except that optical structure 12-1 comprises two couplers 12B-1 and 12B-2 each of which is connected to optical resonator 12A by a respective waveguide 13. Coupler 12B-1 may, for example, be dedicated as an IN port configured to receive photons from the quantum network and coupler 12B-2 may, for example, be dedicated as an OUT port configured to couple photons from quantum systems 11 into a respective optical path (not shown in FIG. 1B-2). In other embodiments an optical path may be applied to carry photons both into and out of a coupler 12B.

Couplers 12B may be arranged in any suitable manner. For example, couplers 12B may be arranged in a regular or irregular 2-dimensional array and/or arrayed along a line, and/or arrayed along two or more lines. Advantageously, couplers 12B may be situated at locations convenient to quantum systems 11 or local groups of quantum systems 11.

As shown for example in FIG. 1D-1, an optical structure 12 can optionally include a plurality of optical resonators 12A which are coupled to a plurality of couplers 12B through a switching device 12D (In FIG. 1D-1, a 3×3 switch). A single photon emitted from a quantum system 11 associated with any one of the plural optical resonators 12A may be delivered into an optical fiber coupled to the corresponding one of the plurality of couplers 12B. In some embodiments switching device 12D such as an optical switch, frequency multiplexer or the like is configured to selectively deliver photons from one of two or more quantum systems 11 to one of the plurality of couplers 12B.

In some embodiments, switching device 12D is configured to simultaneously route photons from two or more quantum systems 11 to a respective coupler 12B based on a configuration of switching device 12D.

Optical structures 12 and their associated optical paths may be applied to connect pairs of quantum systems 11 to a Bell state analyzer (BSA). One type of BSA comprises first and second input ports and first and second output ports. The first and second input ports are respectively connected to receive a photon from a first quantum system 11 and a second quantum system 11. The photons are each generated in a way that results in the quantum state of each of the photons (“photon state”) being entangled with the quantum state of the quantum system 11 from which the photon was emitted. The BSA input ports deliver the respective photons to a device such as a beamsplitter or Mach-Zehnder interferometer that allows the photons to interfere with one another. The first and second output ports are respectively connected to first and second single photon detectors.

The BSA may be used to entangle the quantum states of the first and second quantum systems in a heralded entanglement protocol. An example of a heralded entanglement protocol is described in S. D. Barrett and P. Kok, Phys. Rev. A 71, 060310(R) (2005) which is hereby incorporated herein by reference for all purposes.

The resulting entanglement may be applied (i.e. put to practical use) to perform quantum operations, for example, to teleport the quantum state of one of quantum systems 11 to another quantum system 11 or to teleport a two-qubit quantum gate such that the gate is applied between two quantum systems 11 that are not necessarily local to one another. BSAs may be integrated into a unit 10 and/or may be located off of unit 10.

FIG. 1D-2 is a schematic illustration showing another example optical structure 12-4. Optical structure 12-4 is similar to optical structure 12-3 except that optical structure 12-4 comprises a plurality of nodes 102 as well as an off-chip switch 12D. Nodes 102 may be formed in any of integrated device layer 10B, first adjacent layer 10A and/or second adjacent layer 10B in a unit 10. In FIG. 1D-2 nodes 102 are formed in integrated device layer 10B.

A node 102 may contain one or more quantum systems 11 and optionally one or more intra-node BSA 16A. An intra-node BSA 16A may, for example be applied to entangle two quantum systems 11 within the same node.

In some embodiments at least one quantum system 11 (which may be designated a “network” quantum system) within a node 102 is optically connected to one or more inter-node BSAs 16B by optical paths 15 such as integrated waveguides, optical fibers and/or free space paths An inter-node BSA is a BSA that is connectible to perform a BSM on quantum systems that are located in different nodes. An inter-node BSA may be included within a node be external to any node.

In some embodiments a node 102 may additionally include one or more quantum systems 11 in quantum communication with a network quantum system 11 of the node and/or intra-node BSA 16A by way of intra-node optical paths. These additional quantum systems 11 are not optically connected to any inter-node BSAs 16B outside the node.

Operations on quantum systems 11 within a node (intra-node operations) such as creating entanglement, two-qubit gates, and the like may be more fidelity-preserving than similar operations applied between quantum systems of different nodes (inter-node operations). In some embodiments quantum systems 11 within a node may be entangled through deterministic entanglement protocols. In some embodiments quantum systems 11 within a node may be coupled to one another, for example, by overlapping wavefunctions which result in hyperfine coupling or tunable dipole coupling. Such coupling may facilitate entanglement of the quantum systems 11. For example, entanglement of quantum system coupled by the hyperfine interaction may be achieved by delivering microwave pulses to the quantum systems and entanglement of quantum systems coupled by a tunable dipole interaction may be achieved by tuning the dipolar coupling.

In FIG. 1D-2 a coupler 12B is configured to deliver photons from a corresponding node 102 to an off-chip switch 12D in the off-chip part 10D of a quantum network by being connected to the corresponding node via a waveguide 13. Off-chip switch 12D is configured to selectively route photons from any one of the plurality of nodes to a destination by optical paths 15 based on a configuration of off-chip switch 12D. In some embodiments photons from nodes 102 are selectively routed by off-chip switch 12D to inter-node BSAs. Inter-node BSAs are optionally provided by a unit dedicated to BSAs and/or provided on units containing one or more nodes and/or integrated into individual nodes. Optical paths leading to an inter-node BSA that is part of a unit 10 may be integrated into the unit 10 or may have parts that leave the unit (for example in optical fibers and/or free-space transmission).

FIG. 1E-1 is a schematic top view of a system 100E comprising a unit 10 and optical paths 15 arranged to optically connect quantum systems 11 to BSAs 16 which, in this embodiment are provided in integrated optical layer 10B of unit 10. FIG. 1E-2 is a schematic illustration showing a perspective view of system 100E.

In system 100E optical paths 15 are provided by a “knot” 17 (represented by dashed rounded rectangle in FIG. 1E-1) in which each of optical paths 15 is defined by a light guide 15A that extends between two different couplers 12B of unit 10. The light guides 15A of knot 17 provide optical connections between different parts of unit 10. For example, in FIGS. 1E-1 and 1E-2 light guides 15A of knot 17 provide optical connections between quantum systems 11 and BSAs 16.

System 100E comprises optical switches 12D (each shown as 1×2 switch in FIG. 1E-1) that are optically connected to couplers 12B which are coupled to optical resonators 12A. Switches 12D are configurable to selectively route photons from quantum systems 11 to a coupler 12B of a BSA 16.

For example, a coupler 12B-1 is operable to deliver a photon from a quantum system 11-1 to a switch 12D-1 which can be configured to deliver the photon into light guide 15A-1 which guides the photon to a coupler 12B-2 which is operable to deliver the single photon to a corresponding input port of a BSA 16-1.

In some embodiments system 100E is configured or configurable to deliver single photons originating from one optical resonator 100A to another one of optical resonators 12A (for example, when quantum systems 11 operate in a strongly coupled regime). In some embodiments system 100E is configured or configurable to deliver a single photon originating from a quantum system 11 to a node 102 that contains other quantum systems 11 and a BSA. System 100E may comprise optical switches that are configurable to route the single photon to the BSA in the node.

In some embodiments, optical paths 15 are constructed to provide calibrated delays of photons. For example optical paths 15 connected to first and second input ports of a BSA may be length matched such that photons that enter the optical paths 15 at the same time are delivered to the BSA at the same time. As another example optical paths 15 connected to first and second input ports of a BSA may be selected to delay photons by different amounts to compensate for a difference between times at which photons are emitted by the respective quantum systems 11.

It is not necessary that all quantum systems 11 in a system like system 100A be hosted in one unit 10. A system may include plural units 10. Different units 10 may be the same or different. In such embodiments light guides may be provided to connect pairs of quantum systems 11, which may be located on the same or different units 10 to corresponding inputs of a BSA. The BSA may be hosted on the same unit 10 as one of the quantum systems 11, a different unit 10 or a separate unit that comprises one or more BSAs.

A BSA may be divided across different units. For example, a beam splitter or other device for promoting interference between photon states may be provided on a first unit, single photon detectors may be provided on a second unit and suitable light guides may carry photon states from output ports of the beam splitter to respective single photon detectors.

In systems where optical paths 15 connect components (e.g. quantum systems 11, nodes containing quantum systems 11, BSAs 16 and/or single photon detectors for BSAs 16) that are distributed across two or more units 10 (such that at least some of the optical paths 15 extend between couplers 12B located on different units 10) then the arrangement of optical paths 15 may be considered to provide a “braid”. A set of optical paths 15 that all extend between different couplers 12B that are on the same unit 10 may be considered to provide a “knot”

FIG. 1F schematically illustrates a system 100F that is similar to system 100A but comprises a plurality of units 10 (labelled 10-1, 10-2 . . . 10-N) with optical interconnections provided by a braid 18 made up of light guides 15A. In system 100F, BSAs 16 are provided by a unit 19 that is separate from units 10. Units 10 of system 100F may be close together or separated by significant distances.

In some embodiments one or more BSAs 16 are provided in an optical assembly that has three or more input ports and includes optical switches arranged to cause a selected pair of the input ports to be connected respectively to first and second input ports of a BSA 16. FIG. 1G shows an example optical assembly 116 that has M input ports with M>2, a BSA 16 and a M×2 switch operable to connect any two of the M input ports to first and second input ports of the BSA 16 by light guides 15A. Each of the M input ports may be optically coupled to a corresponding coupler 12B and may thereby receive photons from a quantum system 11.

In any system that includes a knot 17 or a braid 18 where the knot 17 or braid 18 connects to a unit 10 that operates at cryogenic temperatures portions of the knot or braid optionally pass through an environment in which the temperature of the knot or braid is not at a cryogenic temperature (e.g. room temperature). This provides flexibility in design and also permits a construction in which the topology of a network can be reconfigured by changing room temperature components without any necessity of bringing cryogenic components to room temperature. For example, the knot or braid may include a plurality of light guides such as optical fibers that are each optically coupled to a coupler 12B that is on one of one or more units 10 that are located in one or more cryogenic chambers. These light guides extend to locations outside of the cryogenic chamber. These light guides may then be coupled to an interchangeable part of the knot or braid that provides a desired interconnectivity between the couplers 12B of the system.

For example, a system that includes a plurality of nodes or quantum systems each optically coupled to a coupler 12B might selectively be configured with a first topology that interconnects all of the couplers 12B in a single network that is not all-to-all connected or a second topology that provides two smaller networks. Switching between the first and second topologies may be accomplished by replacing the interchangeable part of the braid or knot with a different interchangeable part.

Systems like system 100A-1 to 100A-3, 100E, 100F or 100J may be implemented to provide various advantages. For example, optical paths 15 may have relatively low loss of photons as compared to waveguides of similar length formed in integrated device layer 10B. The reduced photon loss can facilitate achieving entanglement of quantum systems 11 in fewer attempts. Another example is that the connectivity of units 10 may be changed by replacing one knot 17 or braid 18 with another knot 17 or braid 18 in which light guides or other optical paths 15 are arranged to make different connections. Another example is that a knot 17 may be configured to provide connectivity in the form of a non-planar graph without requiring any crossing waveguides in integrated device layer 10B. Another example is that integrated device layer 10B can have a simplified structure that may be easier to make and/or may provide more room to allow a denser or more optimum arrangement of quantum systems 11 than would be practical if all interconnections were provided by waveguides in integrated device layer 10B. Another example is that a unit 10 may comprise a number of identical nodes. Each of the identical nodes may include at least one quantum system 11 and at least one coupler 12B. Interconnectivity between the nodes may be determined by the connections provided by a particular knot 17 or braid 18. Another example is that a knot 17 or braid 18 can be configured to provide interconnectivity of quantum systems 11 in a desired topology while accommodating any desired distribution of quantum systems 11 over any number of distinct units 10. Another example is that providing interconnections by a knot 17 or braid 18 relaxes constraints regarding where quantum systems 11 and nodes that incorporate quantum systems 11 can be physically located relative to BSAs and other light detector. For example, where connectivity is provided by a braid 18 it is simple to provide a desired network topology even where BSAs are provided on one unit and the quantum systems 11 are provided on another unit. Units carrying single photon detectors for the BSAs and units carrying the quantum systems 11 may even be in separate refrigerators since operation of a braid does not, in general, require the entire braid to be cooled to cryogenic temperatures. Another example is that a knot 17 or braid 18 can accommodate cases in which some quantum systems 11 and/or optical systems 12 are defective by simply avoiding quantum systems 11/optical structures 12 that do not perform well.

For clarity, FIGS. 1A to 1G and 2A to 2C omit various elements that may be provided to: maintain appropriate conditions for operation of quantum systems 11, store quantum information, manipulate quantum states of quantum systems 11 and/or perform measurements on quantum systems 11. A control system 20 which includes some examples of such elements is shown schematically in FIG. 1H. Any embodiment described herein may include a suitable control system 20.

In some embodiments control system 20 of FIG. 1H includes a refrigerator 27 which maintains devices 10 at a desired operating temperature. The desired operating temperature is typically a cryogenic temperature. The operating temperature may, for example be in the range of milliKelvin to 5 Kelvin. In some embodiments the desired operating temperature is at room temperature.

Control system 20 includes a magnetic field generator 21 which applies a magnetic field having a desired direction and magnitude to unit 10.

Control system 20 includes a RF source 22 arranged to deliver radiofrequency signals to quantum systems 11. As known in the art, quantum states of quantum systems 11 may be manipulated by delivering specific pulses or sequences of pulses of RF energy to a quantum system 11.

Control system 20 includes one or more light sources (e.g. lasers) 23. As known in the art, a quantum system 11 may be caused to undergo a state transition by illuminating the quantum system 11 with light having a wavelength selected to cause the transition.

Control system 20 includes an energy level control 24. Energy level control 24 is operable to control energy levels of individual quantum systems 11. Energy level control 24 may, for example, comprise one or more of the following: a source of electrical potential 24A operable to alter an electric field at a quantum system 11; a strain adjustment mechanism 24B operable to adjust strain at a location of a quantum system 11; and a local magnetic field generator 24C operable to vary a magnetic field at a location of a quantum system 11. By controlling the energy levels of quantum systems 11 it is possible to set the wavelengths of photons emitted by an individual quantum system 11 and/or to alter whether an individual quantum system 11 will be induced to undergo a particular transition in response to being exposed to light or other electromagnetic radiation having a particular wavelength.

Control system 20 includes a measurement system 25 operable to make measurements on quantum systems 11.

Control system 20 includes a controller 26 which controls the overall operation of control system 20. Controller 26 may be implemented by one or more of specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”). Examples of programmable data processors are: microprocessors, digital signal processors (“DSPs”), embedded processors, graphics processors, math co-processors, general purpose computers, server computers, cloud computers, mainframe computers, computer workstations, and the like. For example, one or more data processors in a control circuit for a device may implement methods as described herein by executing software instructions in a program memory accessible to the processors and controlling elements of control system 20 according to the software instructions.

### Example Constructions for Knots and Braids

A knot 17 or braid 18 for use in an optical quantum network as disclosed herein (e.g. network 100A-300) may be constructed in various ways. In some embodiments a knot 17 or braid 18 is composed of a set of optical fibers or other suitable light guides that each extend between two couplers 12B on the same or different units 10. Ends of the light guides may be held in place by being affixed to the unit(s) 10 and/or to support structures that hold ends of the light guides at locations that match locations of couplers 12B on a unit 10. In some embodiments the support structures include registration features (e.g. posts, recesses, walls, which allow one or more units 10 to be registered to the support structures in positions and orientations determined by the registration features.

In some embodiments light guides that make up a knot or braid are supported to follow desired paths by a three-dimensional support structure that has one or more surface at which ends of light guides can interface to couplers 12B of one or more units 10. Ends of the light guides may be anchored to the surface at locations comprising to couplers 12B of one or more units 10. In such embodiments the support structure may include passages that define paths to be taken by optical fibers or other light guides between two corresponding couplers 12B.

A three dimensional support structure may have various constructions. In some embodiments a three dimensional support structure includes passages that are formed to guide individual light guides along a desired path between locations corresponding to couplers 12B of one or more units 10. Such support structures may, for example, be created by additive manufacturing (or 3D printing). For example a support structure may comprise a block of material having one or more faces at which light guides may interface to units 10. Passages are formed to extend through the block of material. In some embodiments, each passage is dedicated to a specific light guide. Suitable light guides such as optical fibers may be fed though each of the passages. Ends of the passages may be aligned at locations that will correspond to couplers 12B of units 10 that are interfaced to one or more faces of the support structure. The passages may be designed so that the light guides each have a desired length. The passages may be configured so that the paths followed by each of the light guides lack kinks or sharp bends that could cause excessive photon loss. The passages may be configured so that the light guides emerge from the passages at correct locations to interface with couplers 12B and in correct orientations to interface with couplers 12B.

In some embodiments light guides are also formed by additive manufacturing. For example, an additive manufacturing process may be applied to build both a support structure and light guides that are supported in or on the support structure. The light guide portions of the structure may be formed of suitable optically transparent materials.

In some embodiments paths for individual light guides are established by an optimization process that finds optimized paths for the light guides taking into account locations and orientations for ends of the light guides to interface to couplers 12B of one or more units 10, path length, avoiding intersections with paths of other light guides, and/or avoiding tight bends, kinks or other configurations likely to increase photon loss. The optimization may, for example comprise starting with an “ideal” path for each of the light guides (e.g. a smooth path determined by applying a suitable mathematical function to connect ends of the light guide at the correct positions and orientations), identifying locations where there is conflict between the ideal paths for different light guides and iteratively modifying the paths to avoid the conflict.

In some embodiments the support structure is modelled based on a particular network geometry and connectivity (e.g. number of units 10, number of endpoints, the connectivity map, etc.). The model may be created with computer aided design (CAD) software. Layers of the support structure corresponding to slices of the CAD model. The CAD model may be optimized by moving locations at which light guides intersect each of the layers subject to constraints such as constraints that limit the curvature of the light guides.

A support structure for all or a portion of a knot 17 or braid 18 may be formed in any suitable shape to complement the physical geometry of a particular network. For example, the support structure may have the form of a cube, a rectangular prism, a triangular prism, a hexagonal prism etc. The support structure may have one or more faces. One or more of the faces includes a plurality of connection endpoints arranged in a pattern that corresponds to couplers 12B of a unit 10. One or more units 10 may interface to light guides supported by the support structure that end at locations corresponding to patterns of couplers 12 provided on the units 10. For a knot 17 the support structure is paired with one unit 10. For a braid 18 the support structure is paired with two or more units 10.

In some embodiments a knot or braid is reconfigurable. In such embodiments, the optical connectivity provided by the knot or braid may be altered by replacing one or more of the light guides and/or moving one or more endpoint of one or more of the light guides. For example, a knot 17 or braid 18 may include one or more support structures that is configured to interface to a unit. The support structure(s) may be configured to support ends of light guides at positions that correspond to optical ports of the unit. The support structure(s) may be configured to provide a plurality of positions at which ends of light guides may be releasably held at positions and angles such that the light guide is optically coupled to an optical port on a unit. The support structure may, for example include an array of positions each operable to releasably hold one end of an optical fiber. Optical connectivity to optical ports on the unit may be changed by rearranging the light guides among positions corresponding to optical ports of the unit. The braid 17 or knot 18 may be reconfigured from a configuration for interfacing to a first unit to a configuration for interfacing to a second unit having a different number of ports and/or ports in different locations by connecting ends of light guides to the support structure at positions corresponding to ports of the second unit.

A reconfigurable structure facilitates changing a connectivity mapping of a braid 18 or a knot 17 of a network without having to replace all components of the network. For example, the connectivity mapping of a braid may be reconfigured by replacing the unit containing BSAs with a new unit containing a different array of BSAs while reconfiguring the endpoints of the light guides on the face of a support structure to which the unit that includes the BSAs interfaces. The endpoints may be reconfigured, for example, by adjusting which apertures of a grid of apertures the ends of light guides pass through to couple to corresponding couplers of a unit 10.

In some embodiments a reconfigurable structure is designed according to a pre-determined layout of grid of apertures. In some embodiments a reconfigurable structure is manufactured with customized grid of apertures for one or more of the 2D layers based on a computer aided design (CAD) model. The CAD may be based on a modelling of a selected connectivity mapping where the layout of the grid of apertures of each layer is based on a corresponding slice of the CAD model.

As described above, knots 17 and/or braids 18 may be configured to interconnect quantum systems 11 according to any of a wide range of topologies. Each of these topologies corresponds to a hardware graph.

### Examples of Included Variations

The present technology is not limited to application to quantum systems of any particular type although it is currently considered that quantum systems such as T centers in a crystalline substrate have significant advantages in comparison to other types of quantum systems that may be used to store and manipulate quantum information. Nodes of networks as described herein may include other types of quantum systems such as: spin-photon interfaces that interact with other neighboring spins; ion traps with multiple ions in the same trap; ensembles of superconducting qubits combined with a transducer that performs transduction of microwave photon states from at least one of the superconducting qubits to optical photons.

In some embodiments, some components of a quantum network as described herein (e.g. quantum systems, optical switches, BSAs, and/or optical waveguides etc are included on substrates or chips. Components of a network may be formed on one substrate or chip or distributed among plural substrates or chips. Some components may not be provided on a substrate or chip. Components may be may be allocated among substrates or chips in any suitable manner. In some embodiments, quantum systems of each node of a network are formed on one substrate or chip and BSAs are one or more of: integrated into nodes, supported on a chip that also hosts one or more nodes, or located on chip(s) or substrate(s) that do not include nodes, etc.

Where a component (e.g. a software module, processor, assembly, device, circuit, etc.) is referred to herein, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

The invention may also be provided in the form of a program product. The program product may comprise any non-transitory medium which carries a set of computer-readable instructions which, when executed by a data processor, cause the data processor to execute a method of the invention. Program products according to the invention may be in any of a wide variety of forms. The program product may comprise, for example, non-transitory media such as magnetic data storage media including floppy diskettes, hard disk drives, optical data storage media including CD ROMs, DVDs, electronic data storage media including ROMs, flash RAM, EPROMS, hardwired or preprogrammed chips (e.g., EEPROM semiconductor chips), nanotechnology memory, or the like. The computer-readable signals on the program product may optionally be compressed or encrypted.

In some embodiments, the invention may be implemented in software. For greater clarity, “software” includes any instructions executed on a processor, and may include (but is not limited to) firmware, resident software, microcode, code for configuring a configurable logic circuit, applications, apps, and the like. Both processing hardware and software may be centralized or distributed (or a combination thereof), in whole or in part, as known to those skilled in the art. For example, software and other modules may be accessible via local memory, via a network, via a browser or other application in a distributed computing context, or via other means suitable for the purposes described above.

Software and other modules may reside on servers, workstations, personal computers, tablet computers, and other devices suitable for the purposes described herein.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms. These terms (“a”, “an”, and “the”) mean one or more unless stated otherwise;
“and/or” is used to indicate one or both stated cases may occur, for example A and/or B includes both (A and B) and (A or B);
“approximately” when applied to a numerical value means the numerical value ±10%;
where a feature is described as being “optional” or “optionally” present or described as being present “in some embodiments” it is intended that the present disclosure encompasses embodiments where that feature is present and other embodiments where that feature is not necessarily present and other embodiments where that feature is excluded. Further, where any combination of features is described in this application this statement is intended to serve as antecedent basis for the use of exclusive terminology such as “solely,” “only” and the like in relation to the combination of features as well as the use of “negative” limitation(s)” to exclude the presence of other features; and
“first” and “second” are used for descriptive purposes and cannot be understood as indicating or implying relative importance or indicating the number of indicated technical features.

Words that indicate directions such as “vertical”, “transverse”, “horizontal”, “upward”, “downward”, “forward”, “backward”, “inward”, “outward”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Where a range for a value is stated, the stated range includes all sub-ranges of the range. It is intended that the statement of a range supports the value being at an endpoint of the range as well as at any intervening value to the tenth of the unit of the lower limit of the range, as well as any subrange or sets of sub ranges of the range unless the context clearly dictates otherwise or any portion(s) of the stated range is specifically excluded. Where the stated range includes one or both endpoints of the range, ranges excluding either or both of those included endpoints are also included in the invention.

Certain numerical values described herein are preceded by “about”. In this context, “about” provides literal support for the exact numerical value that it precedes, the exact numerical value ±5%, as well as all other numerical values that are near to or approximately equal to that numerical value. Unless otherwise indicated a particular numerical value is included in “about” a specifically recited numerical value where the particular numerical value provides the substantial equivalent of the specifically recited numerical value in the context in which the specifically recited numerical value is presented. For example, a statement that something has the numerical value of “about 10” is to be interpreted as: the set of statements:
in some embodiments the numerical value is 10;
in some embodiments the numerical value is in the range of 9.5 to 10.5;
and if from the context the person of ordinary skill in the art would understand that values within a certain range are substantially equivalent to 10 because the values with the range would be understood to provide substantially the same result as the value 10 then “about 10” also includes:
in some embodiments the numerical value is in the range of C to D where C and D are respectively lower and upper endpoints of the range that encompasses all of those values that provide a substantial equivalent to the value 10

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

As will be apparent to those of skill in the art upon reading this disclosure, each of the individual embodiments described and illustrated herein has discrete components and features which may be readily separated from or combined with the features of any other described embodiment(s) without departing from the scope of the present invention.

Any aspects described above in reference to apparatus may also apply to methods and vice versa.

Any recited method can be carried out in the order of events recited or in any other order which is logically possible. For example, while processes or blocks are presented in a given order, alternative examples may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, simultaneously or at different times.

Various features are described herein as being present in “some embodiments”. Such features are not mandatory and may not be present in all embodiments. Embodiments of the invention may include zero, any one or any combination of two or more of such features. All possible combinations of such features are contemplated by this disclosure even where such features are shown in different drawings and/or described in different sections or paragraphs. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible). This is the case even if features A and B are illustrated in different drawings and/or mentioned in different paragraphs, sections or sentences.

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

1. A quantum network having a non-all-to-all network topology characterized by a connected entanglement graph comprising a plurality of vertices and a plurality of edges, each of the edges joining a pair of vertices, wherein at least some of the vertices are joined to three or more other ones of the vertices by three or more of the edges, the quantum network comprising:
a plurality of nodes, each of the nodes corresponding to a vertex of the entanglement graph and comprising at least one quantum system having a quantum state configurable to store quantum information for a quantum informatics process, the plurality of nodes including
$$\frac{N ( N - 1 )}{2}$$
distinct pairs of nodes where N is the number of the nodes; and
entanglement means exclusively operable on those of the pairs of nodes which respectively correspond to pairs of vertices of the entanglement graph that are joined by one of the edges, the entanglement means for pairwise entangling quantum systems that are respectively located at different nodes of any of the pairs of the nodes which correspond to vertices of the entanglement graph that are joined by one of the edges.

2. The quantum network of claim 1 wherein the entanglement means comprises:
one or more Bell state analyzer (BSA) having first and second input ports and,
for each of the pairs of nodes which respectively correspond to pairs of vertices of the entanglement graph that are joined by one of the edges, a corresponding pair of first and second optical paths respectively providing optical coupling of first and second nodes of the pair of nodes to the first and second input ports of the BSA.

3. The quantum network of claim 2 wherein at least some of the optical paths include a free space optical path.

4. The quantum network of claim 2 wherein at least some of the optical paths include an optical fiber.

5. The quantum network of claim 2 wherein the quantum systems comprise electron spins.

6. The quantum network of claim 1 wherein the entanglement means comprises:
for each of the pairs of nodes which respectively correspond to pairs of vertices of the entanglement graph that are joined by one of the edges, one or more shuttle paths, the one or more shuttle paths operable to bring two of the quantum systems that are to be pairwise entangled to a common location; and
a control system operable to entangle the two of the quantum systems that are to be pairwise entangled by applying one or more quantum gates to the two of the quantum systems.

7. The quantum network according to claim 6 wherein the quantum systems comprise trapped ions or quantum dots.

8. The quantum network of claim 1 wherein the entanglement means comprises:
for each of the pairs of nodes that correspond to a pair of the vertices of the entanglement graph that are joined by one of the edges, an electronic circuit operable to couple quantum systems that are to be pairwise entangled; and
a control system operable to entangle the quantum systems that are to be pairwise entangled by applying one or more quantum gates to the quantum systems.

9. The quantum network according to claim 8 wherein the quantum systems comprise superconducting Josephson junctions.

10. The quantum network according to claim 1 wherein the entanglement graph is a regular graph.

11. The quantum network according to claim 10 wherein the regular graph is a strongly regular graph.

12. The quantum network of claim 10 wherein the regular graph comprises one or more dangling vertices, each of the dangling vertices joined to at most one other vertex of the regular graph.

13. The quantum network according to claim 1 wherein the entanglement graph comprises a plurality of distinct subsets of the vertices that are all-to-all connected, each of the subsets of the vertices being made up of M vertices, and for each of the subsets of the vertices none of the vertices of the entanglement graph that does not belong to the subset of the vertices is connected by respective edges to every one of the vertices of the subset of the vertices.

14. (canceled)

15. The quantum network according to claim 1 comprising a control system configured to create entanglement between first and second ones of the quantum systems that are respectively associated with first and second ones of the nodes corresponding to vertices of the entanglement graph that are not joined by an edge by:
controlling the entanglement means to create a plurality of entangled pairs of the quantum systems, one of the plurality of entangled pairs of the quantum systems including the first one of the quantum systems and another one of the plurality of entangled pairs of the quantum systems including the second one of the quantum systems; and
performing entanglement swapping to cause the first and second ones of the quantum systems to be entangled.

16. The quantum network according to claim 1 comprising a control system configured to create entanglement between first and second ones of the quantum systems that are respectively associated with first and second ones of the nodes corresponding to vertices of the entanglement graph that are not joined by an edge by:
routing a travelling qubit associated with the first one of the quantum systems to the node associated with the second one of the quantum systems, and
executing, at the node associated with the second one of the quantum systems, an entanglement protocol on the travelling qubit associated with the first one of the quantum systems and a travelling qubit associated with the second one of the quantum systems.

17. The quantum network according to claim 16, wherein routing the travelling qubit associated with the first one of the quantum systems comprises routing the travelling qubit along a path that passes through one or more intermediary nodes.

18. The quantum network according to claim 17 wherein, each of the one or more intermediary nodes includes one or more switches that is configurable to allow the travelling qubit to traverse the intermediary node and to block the travelling qubit from interacting with quantum systems of the intermediary node.

19-66. (canceled)

67. The quantum network according to claim 1, wherein the quantum systems comprise luminescent centers.

68. The quantum network according to claim 67, wherein the luminescent centers comprise a T-center.

69. The quantum network according to claim 1, wherein each node comprises a broker quantum system and a plurality of client quantum systems coupled to the broker quantum system.
